(19) United States
(12) Patent Application Publication
(10) Pub. No.: US 2026/0040561 A1
(43) Pub. Date: Feb. 5, 2026

(54) MICROELECTRONIC DEVICES AND RELATED MEMORY DEVICES

(71) Applicant: Micron Technology, Inc., Boise, ID (US)

(72) Inventors: Christophe Vincent Antoine Laurent, Agrate Brianza (IT); Andrea Martinelli, Bergamo (IT); Efrem Bolandrina, Fiorano Al Serio (IT); Paolo Fantini, Vimercate (IT); Anna Maria Conti, Milano (IT); Paolo Tessariol, Arcore (IT)

(21) Appl. No.: 19/254,596

(22) Filed: Jun. 30, 2025

Related U.S. Application Data
(60) Provisional application No. 63/677,942, filed on Jul. 31, 2024.

(51) Int. Cl. H10B 43/35; H10B 41/20; H10B 41/35; H10B 43/20

(52) U.S. Cl. CPC H10B 43/35; H10B 41/20; H10B 41/35; H10B 43/20

(57) ABSTRACT

A microelectronic device includes a stack structure, block select (BS) devices, and a global word line (GWL) stack. The stack structure has tiers respectively including conductive material. The stack structure is divided into blocks respectively including local word line (LWL) structures vertically stacked relative to one another and individually including a portion of the conductive material of one of the tiers. The BS devices vertically overlap the blocks of the stack structure and respectively include a stack of transistors operatively associated with the LWL structures of one of the blocks. The GWL stack vertically overlaps the BS devices and the blocks of the stack structure and includes GWL structures vertically stacked relative to one another. The GWL stack is operatively associated with multiple of the BS devices. Related memory devices and electronic systems are also described.

### CROSS-REFERENCE TO RELATED APPLICATIONS

This application claims the benefit under 35 U.S.C. § 119(e) of U.S. Provisional Patent Application Ser. No. 63/677,942, filed Jul. 31, 2024, which is related to U.S. Provisional Patent Application Ser. No. 63/677,988, filed on even date herewith, listing Christophe Vincent Antoine Laurent, Andrea Martinelli, Efrem Bolandrina, Paolo Fantini, Anna Maria Conti, and Paolo Tessariol as inventors, for “MICROELECTRONIC DEVICES AND RELATED MEMORY DEVICES.” The disclosure of the foregoing document is hereby incorporated herein in its entirety by reference.

### TECHNICAL FIELD

This disclosure, in various embodiments, relates generally to the field of microelectronic device design and fabrication. More specifically, the disclosure relates to microelectronic devices including global word lines, local word lines, and block select devices, and to related memory devices and electronic systems.

### BACKGROUND

A continuing goal of the microelectronics industry has been to increase the memory density (e.g., the number of memory cells per memory die) of memory devices, such as non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes vertical memory strings extending through openings in tiers of conductive structures (e.g., word line plates) and dielectric materials at each junction of the vertical memory strings and the conductive structures. Such a configuration permits a greater number of switching devices (e.g., transistors) to be located in a unit of die area (i.e., length and width of active surface consumed) by building the array upwards (e.g., longitudinally, vertically) on a die, as compared to structures with conventional planar (e.g., two-dimensional) arrangements of transistors.

Conventional vertical memory arrays include electrical connections between the conductive structures and access lines (e.g., word lines) so that memory cells in the vertical memory array can be uniquely selected for writing, reading, or erasing operations. One method of forming such an electrical connection includes forming so-called at least one “staircase” (or “stair step”) structures at edges (e.g., horizontal ends) of the tiers of conductive structures. The staircase structure includes individual “steps” defining contact regions of the conductive structures upon which conductive contact structures can be positioned to provide electrical access to the conductive structures.

As vertical memory array technology has advanced, additional memory density has been provided by forming vertical memory arrays to include additional tiers of conductive structures and, hence, additional staircase structures and/or additional steps in individual staircase structures associated therewith. However, increasing the quantity of tiers of conductive structures (and, hence, the quantity of staircase structures and/or the quantity of steps in individual staircase structures) of a stack structure without undesirably increasing the overall width (e.g., lateral footprint) of the stack structure can result in complex and congested routing paths to electrically connect the conductive structures to additional components (e.g., string drivers) of the memory device. Such complex and congested routing paths may impede (or even prevent) desirable connection paths from and between other components of the memory device. In addition, as the quantity of tiers of conductive structures continues to increase, conventional locations for and configurations of additional components of the memory device have become unable to support increased quantities of the additional components.

### BRIEF DESCRIPTION OF THE DRAWINGS

FIG. 1 shows a simplified, partial-cutaway perspective view of a microelectronic device, in accordance with some embodiments of the disclosure.

FIGS. 2A through 2D show simplified, partial-cutaway perspective views of different configurations for a block select device of the microelectronic device of FIG. 1, in accordance with various embodiments of the disclosure.

FIGS. 3A and 3B show a schematic, top-down view (FIG. 3A) and a simplified, partial-cutaway perspective view (FIG. 3B) of a portion of the microelectronic device of FIG. 1.

FIGS. 4A and 4B show a schematic, top-down view (FIG. 4A) and a simplified, partial-cutaway perspective view (FIG. 4B) of a portion of a microelectronic device, in accordance with additional embodiments of the disclosure.

FIGS. 5A and 5B show a schematic, top-down view (FIG. 5A) and a simplified, partial-cutaway perspective view (FIG. 5B) of a portion of a microelectronic device, in accordance with further embodiments the disclosure.

FIGS. 6A through 6C show simplified, partial-cutaway perspective views of different feature configurations for an in-tier global word line region of a microelectronic device, in accordance with various embodiments of the disclosure.

FIG. 7 shows a simplified, vertical cross-sectional view of a portion of a microelectronic device encompassing an upper select gate region of a block of a microelectronic device, in accordance with some embodiments of the disclosure.

FIGS. 8A and 8B show simplified, partial-cutaway perspective views of different feature configurations for the upper select gate region of the microelectronic device shown in FIG. 7, in accordance with various embodiments of the disclosure.

FIGS. 9A and 9B show schematic, top-down views of different feature configurations for a microelectronic device, in accordance with various embodiments of the disclosure.

FIG. 10A shows a simplified, partial-cutaway perspective view illustrating contact structure configurations within each of an in-tier global word line region and an in-tier block select region of a microelectronic device, in accordance with some embodiments of the disclosure. FIG. 10B shows a schematic, top-down view of a portion of the in-tier global word line region shown in FIG. 10A. FIG. 10C shows a schematic, top-down view of a portion of the in-tier block select region shown in FIG. 10A.

FIGS. 11A through 11E show simplified plan views of different configurations for a microelectronic device including different arrangements of block sections and global word line regions than one another, in accordance with various embodiments of the disclosure.

FIGS. 12A and 12B show simplified, partial-cutaway perspective views of different configurations for a microelectronic device to facilitate different block select operations for different block sections thereof, in accordance with various embodiments of the disclosure.

FIGS. 13 through 16C (including FIG. 13, FIGS. 14A and 14B, FIGS. 15A through 15E, and FIGS. 16A through 16C) show simplified plan views of different configurations for various control logic circuitry for a microelectronic device, in accordance with some embodiments of the disclosure.

FIG. 17 is a block diagram of an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device, such as 3D NAND Flash memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., materials, structures, regions, circuitry, devices) described as “neighboring” one another means and includes features of the disclosed identity (or identities) that are located most proximate (e.g., closest to) one another. Additional features (e.g., additional material, additional structures, additional regions, additional circuitry, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms following “a,” “an,” and “the” are intended to include the plural forms as well, unless the context clearly indicates otherwise.

As used herein, “and/of” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively-doped semiconductor material (e.g., conductively-doped polysilicon, conductively-doped germanium (Ge), conductively-doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). In addition, an “insulative structure” means and includes a structure formed of and including an insulative material.

As used herein, “semiconductor material” and “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

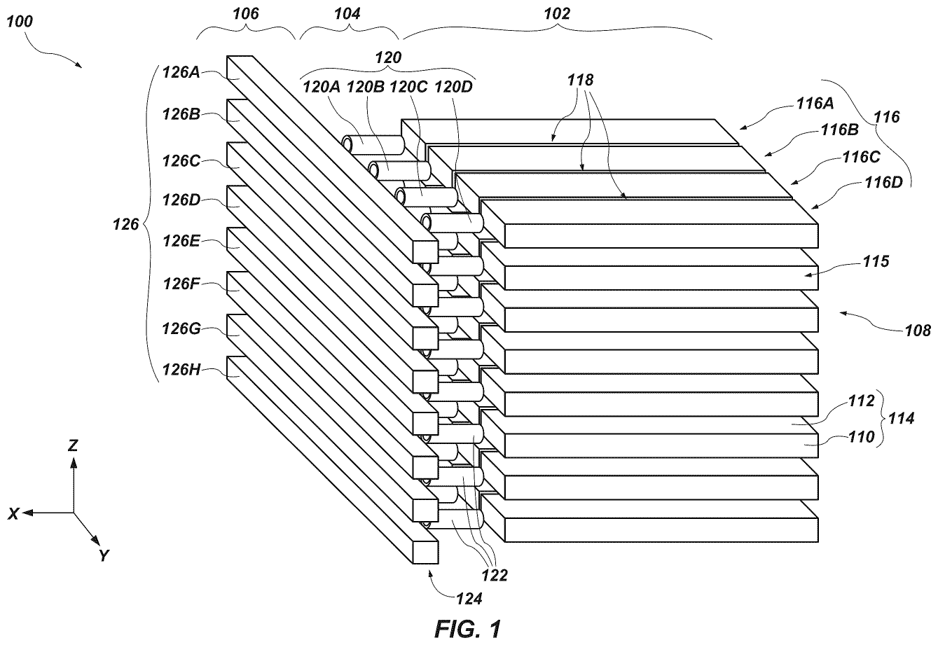

FIG. 1 shows a simplified, partial-cutaway perspective view of a microelectronic device 100, in accordance with some embodiments of the disclosure. The microelectronic device 100 may be formed to include at least one block array region 102, at least one in-tier block select (BS) region 104 horizontally neighboring the block array region 102 in an X-direction (e.g., a first horizontal direction), and at least one in-tier global word line (GWL) region 106 horizontally neighboring the in-tier BS region 104 in the X-direction. As shown in FIG. 1, the in-tier BS region 104 may be horizontally interposed between the block array region 102 and the in-tier GWL region 106 in the X-direction. The block array region 102, in-tier BS region 104, and the in-tier GWL region 106 of the microelectronic device 100 are described in further detail below, as are additional features of the microelectronic device 100.

Within the block array region 102 the microelectronic device 100 includes a stack structure 108 having a vertically alternating (e.g., in the Z-direction) sequence of conductive material 110 and insulative material 112 arranged in tiers 114. The tiers 114 of the stack structure 108 may respectively include the conductive material 110 vertically neighboring the insulative material 112. In some embodiments, the conductive material 110 of respective ones of the tiers 114 is formed of and includes one or more of W, Ru, Mo, and titanium nitride (TiN); and the insulative material 112 of the respective ones of the tiers 114 is formed of and includes silicon dioxide (SiO₂).

As described in further detail below, at least one group (e.g., some) of the tiers 114 of the stack structure 108 are employed as local word line (LWL) tiers for the microelectronic device 100. The group of the tiers 114 employed as LWL tiers may be vertically interposed between the additional groups of tiers 114 employed for different functions within the microelectronic device 100, such as a relatively vertically higher group of the tiers 114 employed as upper select gate (e.g., drain side select gate (SGD)) tiers and a relatively vertically lower group of the tiers 114 employed as lower select gate (e.g., source side select gate (SGS)) tiers. For tiers 114 of the stack structure 108 employed as LWL tiers for the microelectronic device 100, the conductive material 110 thereof may be employed for LWL structures 115 of the microelectronic device 100. For clarity and ease of understanding the drawings and related description, the tiers 114 shown in FIG. 1 may be considered LWL tiers for the microelectronic device 100. However, it will be understood that other tiers 114 may be provided vertically above and/or vertically below the tiers 114 shown in FIG. 1, and at least some of those other tiers 114 may be employed for different function(s) within the microelectronic device 100.

The stack structure 108 may include a desired quantity of the tiers 114. While, for clarity and ease of understanding the drawings and related description, FIG. 1 depicts the stack structure 108 of the microelectronic device 100 as including eight (8) of the tiers 114, the disclosure is not so limited, and the stack structure 108 may include any desired quantity and/or groupings of the tiers 114. For example, the stack structure 108 may include greater than eight (8) of the tiers 114, greater than or equal to sixteen (16) of the tiers 114, greater than or equal to thirty-two (32) of the tiers 114, greater than or equal to sixty-four (64) of the tiers 114, greater than or equal to one hundred twenty-eight (128) of the tiers 114, greater than or equal to two hundred fifty-six (256) of the tiers 114, greater than or equal to five hundred twelve (512) of the tiers 114, or greater than or equal to one thousand twenty-four (1024) of the tiers 114.

Still referring to FIG. 1, the stack structure 108 may be divided (e.g., separated, partitioned) into blocks 116 separated from one another by insulative slot structures 118 (e.g., dielectric-filled slots, dielectric-filled openings). By way of non-limited example, the blocks 116 of the stack structure 108 may include a first block 116A, a second block 116B, a third block 116C, and a fourth block 116D. The insulative slot structures 118 may vertically extend (e.g., in the Z-direction) completely through the stack structure 108. The blocks 116 of the stack structure 108 may horizontally extend in parallel with one another in the X-direction, and may be separated from one another in a Y-direction (e.g., a second horizontal direction) orthogonal to the X-direction by the insulative slot structures 118. As used herein, the term “parallel” means substantially parallel. The insulative slot structures 118 may also horizontally extend in parallel with one another in the X-direction. Each of the blocks 116 of the stack structure 108 may exhibit substantially the same geometric configuration (e.g., substantially the same dimensions and substantially the same shape) as each other of the blocks 116, or one or more of the blocks 116 may exhibit a different geometric configuration (e.g., one or more different dimensions and/or a different shape) than one or more other of the blocks 116. While, for clarity and ease of understanding the drawings and related description, FIG. 1 depicts the microelectronic device 100 as including a group of four (4) of the blocks 116 (e.g., the first block 116A, the second block 116B, the third block 116C, and the fourth block 116D), the disclosure is not so limited, and the microelectronic device 100 may include any desired quantity and/or groupings of the blocks 116. For example, as described in further detail below, the microelectronic device 100 may be formed to include multiple planes of the blocks 116 respectively having a desired quantity of the blocks 116, and/or multiple sub-planes (e.g., separated half-planes of an individual plane, separated quarter-planes of an individual plane) of the blocks 116 respectively having a desired quantity of the blocks 116.

Within horizontal areas of the blocks 116, the microelectronic device 100 includes vertically extending strings of memory cells coupled in series with one another. The memory cells of the strings may be formed at intersections of cell pillar structures vertically extending the stack structure 108 and the conductive material 110 of tiers 114 of the stack structure 108 employed as LWL tiers. In some embodiments, the memory cells comprise so-called “MONOS” (metal-oxide-nitride-oxide-semiconductor) memory cells. In additional embodiments, the memory cells comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells comprise so-called “floating gate” memory cells including floating gates (e.g., metallic floating gates) as charge storage structures. Different groups of the vertically extending strings of memory cells within different blocks 116 of the stack structures form different memory arrays for the microelectronic device 100.

Still referring to FIG. 1, within the in-tier BS region 104 the microelectronic device 100 includes BS devices 120. The BS devices 120 may respectively be positioned within a vertical span (e.g., a vertical extent) of the tiers 114 of the stack structure 108, and, hence, may be considered and are also referred to herein as “in-tier” BS devices 120. The BS devices 120 within the in-tier BS region 104 vertically overlap (e.g., in the Z-direction) and are operatively associated with the blocks 116 of the stack structure 108 within block array region 102. The BS devices 120 may be substantially vertically confined within vertical extents of the blocks 116, such that the BS devices 120 are not substantially vertically offset from the blocks 116. In some embodiments, the BS devices 120 at least partially (e.g., a substantially) vertically overlap a group of the tiers 114 of the stack structure 108 employed as LWL tiers for the microelectronic device 100.

Each of the blocks 116 of the stack structure 108 may include at least one of the BS devices 120 operatively associated therewith. As a non-limiting example, the in-tier BS region 104 may include four (4) BS devices 120 operatively associated with four (4) blocks 116 included within the block array region 102. Each of the four (4) of the blocks 116 may be operatively associated with a different one of the BS devices 120. The BS devices 120 of the in-tier BS region 104 may, for example, include a first BS device 120A operatively associated with the first block 116A, a second BS device 120B operatively associated with the second block 116B, a third BS device 120C operatively associated with the third block 116C, and a fourth BS device 120D operatively associated with the fourth block 116D. For an individual block 116, an individual BS device 120 operatively associated with the block 116 may vertically overlap the block 116 in the Z-direction and may horizontally overlap the block 116 in the Y-direction.

The BS devices 120 may respectively include transistors 122 vertically stacked relative to one another. The transistors 122 may be employed as select transistors (e.g., LWL select transistors, string driver transistors) of the BS devices 120, as described in further details below. An individual BS device 120 may include a quantity of the transistors 122 sufficient to facilitate desirable electrical communication between the LWL structures 115 of an individual block 116 operatively associated with the BS device 120 and GWL structures 126 within the in-tier GWL region 106 of the microelectronic device 100. For example, a quantity of transistors 122 included within an individual BS device 120 may be greater than or equal to a quantity of LWL structures 115 included in an individual block 116 operatively associated with the BS device 120. In some embodiments, a quantity of transistors 122 included within an individual BS device 120 is equal to a quantity of LWL structures 115 included in an individual block 116 operatively associated with the BS device 120. For example, as shown in FIG. 1, if the block 116 includes eight (8) LWL structures 115 (e.g., within eight (8) tiers 114 employed as LWL tiers), the BS device 120 operatively associated with the block 116 may include eight (8) of the transistors 122. Each of the LWL structures 115 of an individual block 116 may be coupled to a respective one of the transistors 122 of an individual BS device 120 vertically overlapping (e.g., in the Z-direction) and horizontally overlapping (e.g., in the Y-direction) the block 116. For an individual LWL structure 115 of an individual block 116, the transistor 122 of a respective BS device 120 operativity associated with the block 116 may be positioned with a vertical span of the tier 114 (e.g., LWL tier) including the LWL structure 115. Hence, the transistors 122 of the BS devices 120 may be considered and are also referred to herein as “in-tier” transistors 122. For an individual LWL structure 115 of an individual block 116, the transistor 122 of a respective BS device 120 operativity associated with the block 116 may at least partially (e.g., substantially) vertically overlap and be coupled to the LWL structure 115.

Still referring to FIG. 1, the in-tier GWL region 106 of the microelectronic device 100 includes a GWL stack 124 including GWL structures 126 vertically stacked relative to one another. The GWL stack 124 may be positioned with a vertical span (e.g., a vertical extent) of the tiers 114 of the stack structure 108, and, hence, may be considered and also referred to herein as an “in-tier” GWL stack 124. The GWL stack 124 vertically overlaps (e.g., in the Z-direction) and is operatively associated with the BS devices 120 within the in-tier BS region 104, as well as the blocks 116 within the block array region 102. The GWL stack 124 may be substantially vertically confined within vertical extents of the blocks 116, such that the GWL stack 124 is not substantially vertically offset from the blocks 116. In some embodiments, the GWL stack 124 at least partially (e.g., a substantially) vertically overlaps a group of the tiers 114 of the stack structure 108 employed as LWL tiers for the microelectronic device 100.

The GWL structures 126 of the GWL stack 124 may individually horizontally extend in the Y-direction, and may at least partially (e.g., substantially) horizontally overlap one another in the X-direction. In some embodiments, horizontally centerlines, in the X-direction, of the GWL structures are substantially horizontally aligned with one another within the in-tier GWL region 106.

The GWL structures 126 may respectively be formed of and include conductive material. In some embodiments, the GWL structures 126 are individually formed of and include one or more of W, Ru, Mo, and TiN.

The GWL stack 124 may include a desired quantity of the GWL structures 126. The quantity of the GWL structures 126 included within the GWL stack 124 may be selected, at least in-part, based on a quantity of tiers 114 of the stack structure 108 employed as LWL tiers (which, as previously described, may also influence a quantity of transistors 122 within an individual BS device 120). For example, a quantity of GWL structures 126 included within the GWL stack 124 may be greater than or equal to a quantity of LWL structures 115 included in an individual block 116 of the stack structure 108. In some embodiments, a quantity of the GWL structures 126 included within the GWL stack is equal to a quantity of the LWL structures 115 included in an individual block 116 of the stack structure 108. For example, as shown in FIG. 1, if the block 116 includes eight (8) LWL structures 115 (e.g., within eight (8) tiers 114 employed as LWL tiers), the GWL stack 124 may include eight (8) of the GWL structures 126 (e.g., a first GWL structure 126A, a second GWL structure 126B, a third GWL structure 126C, a fourth GWL structure 126D, a fifth GWL structure 126E, a sixth GWL structure 126F, a seventh GWL structure 126G, and an eighth GWL structure 126H). Each of the GWL structures 126 of the GWL stack 124 may individually be positioned within a vertical span of an individual tier 114 (e.g., an individual LWL tier) of the stack structure 108. Hence, the GWL structures 126 may be considered and are also referred to herein as “in-tier” GWL structures 126. GWL structures 126 may respectively at least partially (e.g., substantially) vertically overlap the LWL structures 115 (and, thus, the conductive material 110) of an individual tier 114 (e.g., LWL tier) of the stack structure 108.

The GWL stack 124 may be operatively associated with multiple of the BS devices 120 (and, hence, multiple of the blocks 116). For example, if the in-tier BS region 104 includes four (4) BS devices 120 (e.g., the first BS device 120A, the second BS device 120B, the third BS device 120C, the fourth BS device 120D) operatively associated with four (4) blocks 116 (e.g., the first block 116A, the second block 116B, the third block 116C, the fourth block 116D) of the block array region 102, each of the GWL structures 126 of the GWL stack 124 may be operatively associated with each of the four (4) BS devices 120. An individual GWL structure 126 may vertically overlap and be coupled to at least one transistor 122 from each of the four (4) BS devices 120 (e.g., for a total of at least four (4) different transistors 122). As a non-limiting example, the first GWL structure 126A may vertically overlap and be coupled to at least one transistor 122 from each of the first BS device 120A, the second BS device 120B, the third BS device 120C, and the fourth BS device 120D. The transistor 122 of the first BS device 120A may vertically overlap and be coupled to a LWL structure 115 of the first block 116A; the transistor 122 of the second BS device 120B may vertically overlap and be coupled to a LWL structure 115 of the second block 116B; the transistor 122 of the third BS device 120C may vertically overlap and be coupled to a LWL structure 115 of the third block 116C; and the transistor 122 of the fourth BS device 120D may vertically overlap and be coupled to a LWL structure 115 of the fourth block 116D. For a given tier 114 of the stack structure 108 employed as a LWL tier, an individual GWL structure 126 of the GWL stack 124 may vertically overlap multiple LWL structures 115 (e.g., of different blocks 116) within the vertical span of the tier 114; and multiple transistors 122 (e.g., of different BS devices 120) within the vertical span of the tier 114 may individually be coupled to the GWL structure 126 and a respective one of the multiple LWL structures 115.

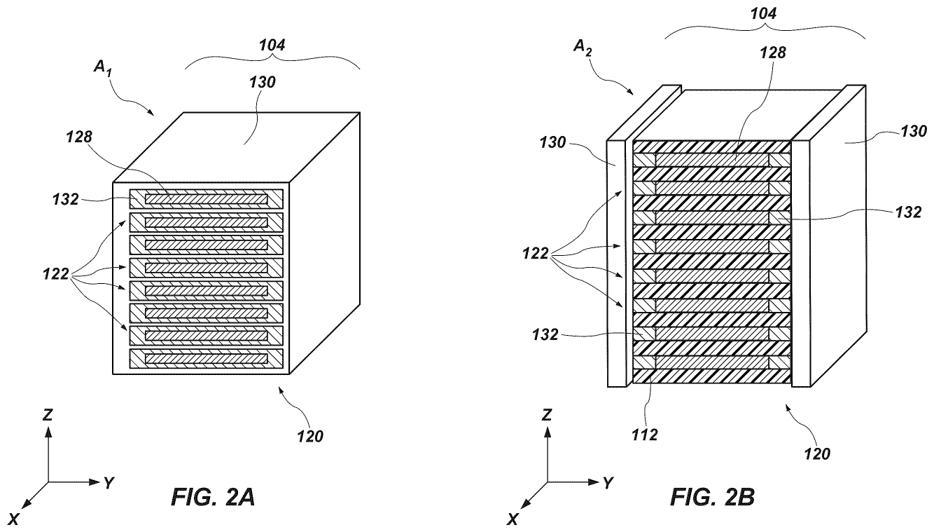

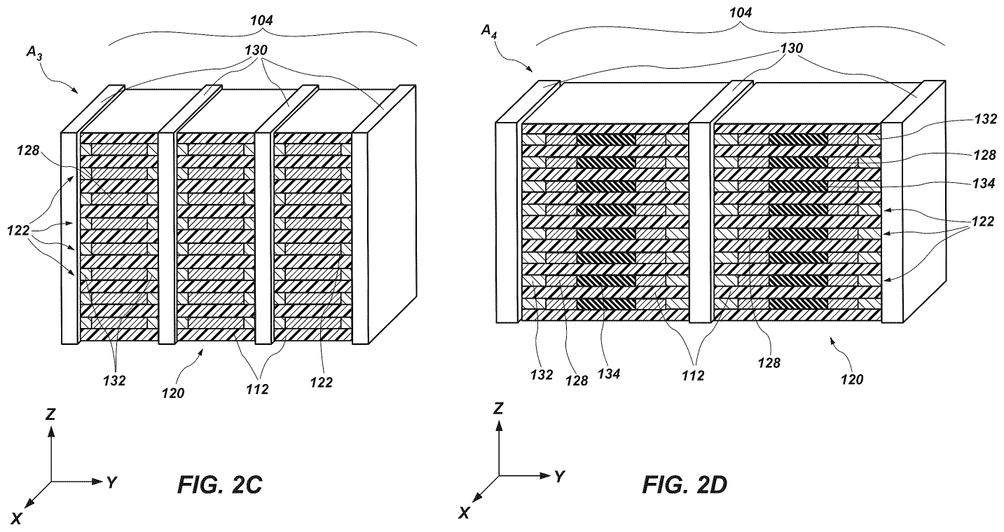

In accordance with embodiments of the disclosure, different features (e.g., structures, materials, regions, circuitry, devices) of the microelectronic device 100 may be formed to exhibit different configurations. For example, in accordance with embodiments of the disclosure, FIGS. 2A through 2D are simplified, partial-cutaway perspective views of different configurations A₁ (FIG. 2A), A₂ (FIG. 2B), A₃ (FIG. 2C), and A₄ (FIG. 2D) that may be employed for an individual BS device 120 of the in-tier BS region 104 of the microelectronic device 100. It will be understood that any of the configurations A₁, A₂, A₃, and A₄ for an BS device 120 shown in FIGS. 2A through 2D and described in further detail below may be employed within the microelectronic device 100, alone or in combination. Additional potential configurations for the microelectronic device 100, including for various features thereof, are also described in further detail below.

Referring to FIG. 2A, an individual BS device 120 within the in-tier BS region 104 may be formed to have a configuration A₁ wherein the transistors 122 thereof respectively have a “gate-all-around” (GAA) configuration. A gate electrode material 130 (effectively serving as one (1) gate electrode) of the BS device 120 may substantially surround four (4) surfaces (e.g., a top surface and a bottom surface opposing one another in the Z-direction, and two side surfaces opposing one another in the Y-direction) of each of a plurality of semiconductor structures 128 vertically stacked relative to one another, and a gate dielectric material 132 may be interposed between the gate electrode material 130 and each of the four (4) surfaces of each semiconductor structure 128 of the plurality of semiconductor structures 128.

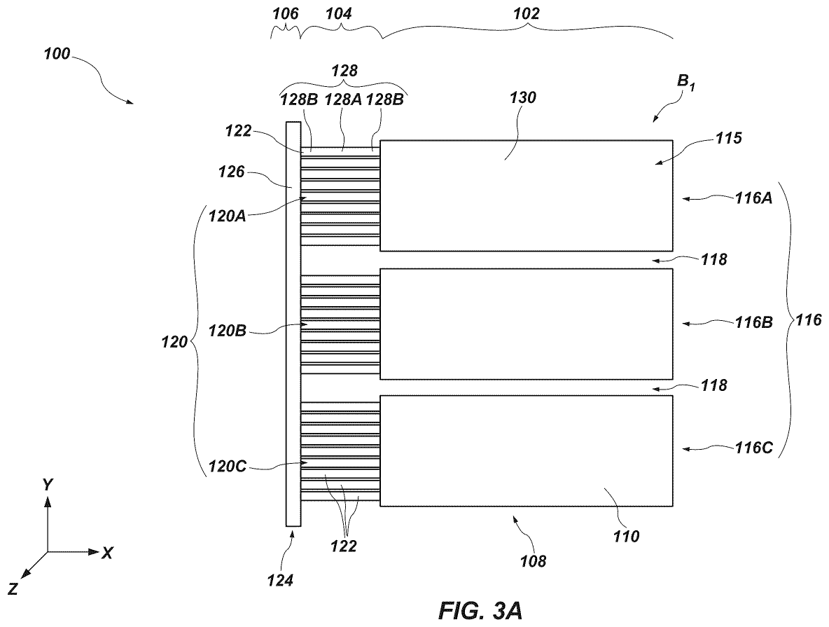

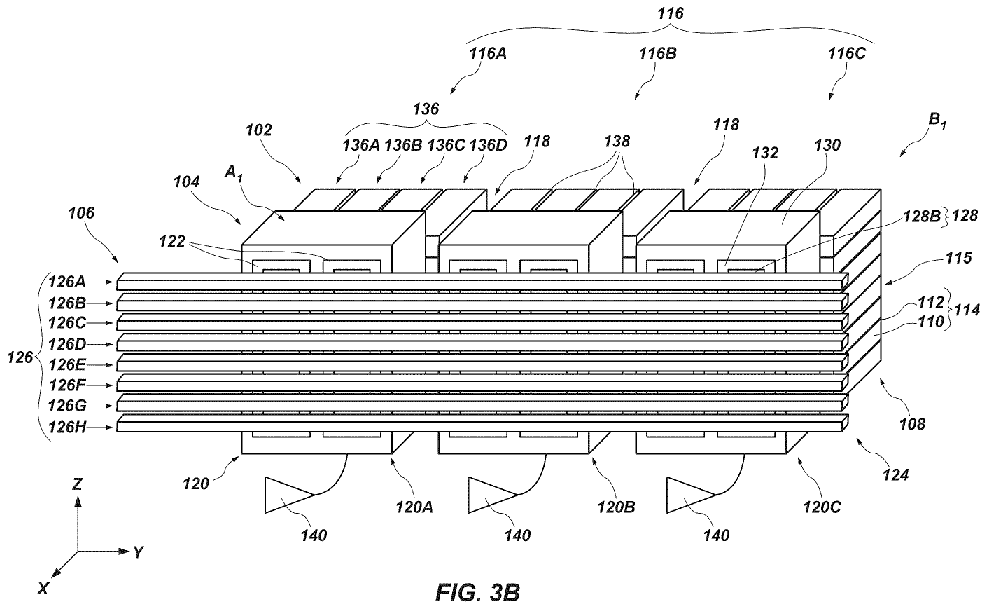

An individual transistor 122 for the configuration A₁ of the BS device 120 shown in FIG. 2A may be considered a GAA transistor, and may include an individual semiconductor structure 128 defining a first source/drain region, a second source/drain region, and a channel region horizontally interposed (e.g., in the X-direction) between the first source/drain region and the second source/drain region (described in further detail below with reference to FIG. 3A); a portion of the gate dielectric material 132 surrounding the semiconductor structure 128; and a portion of the gate electrode material 130 surrounding the portion of the gate dielectric material 132. Within the configuration A₁ shown in FIG. 2A, the gate electrode material 130 may be shared by (e.g., may be common to) each of the transistors 122 of the BS device 120.

Referring next to FIG. 2B, an individual BS device 120 within the in-tier BS region 104 may be formed to have a configuration A₂ wherein the transistors 122 thereof respectively have a “gate-on-two-sides” (G2S) configuration. Two (2) portions of a gate electrode material 130 (effectively serving as two (2) gate electrodes) of the BS device 120 may horizontally neighbor two (2) surfaces (e.g., two side surfaces opposing one another in the Y-direction) of each of a plurality of semiconductor structures 128 vertically stacked relative to one another, and portions of a gate dielectric material 132 may be horizontally interposed between the two (2) portions of the gate electrode material 130 and two (2) surfaces of each semiconductor structure 128 of the plurality of semiconductor structures 128. In addition, the insulative material 112 of the tiers 114 (FIG. 1) of the stack structure 108 (FIG. 1) may be vertically interposed between semiconductor structures 128 vertically neighboring one another within the BS device 120. The insulative material 112 may vertically extend (e.g., in the Z-direction) from and between vertically neighboring semiconductor structures 128 of the BS device 120, and may horizontally extend (e.g., in the Y-direction) from and between the two (2) portions of the gate electrode material 130.

An individual transistor 122 for the configuration A₂ of the BS device 120 shown in FIG. 2B may be considered a G2S transistor, and may include an individual semiconductor structure 128 defining a first source/drain region, a second source/drain region, and a channel region horizontally interposed (e.g., in the X-direction) between the first source/drain region and the second source/drain region (described in further detail below with reference to FIG. 3A); two (2) portions of the gate dielectric material 132 horizontally adjacent (e.g., in the Y-direction) two (2) side surfaces of the semiconductor structure 128; and parts of the two (2) portions of the gate electrode material 130 horizontally adjacent (e.g., in the Y-direction) the two (2) portions of the gate dielectric material 132. Within the configuration A₂ shown in FIG. 2B, the two (2) portions of the gate electrode material 130 may be shared by (e.g., may be common to) each of the transistors 122 of the BS device 120.

Referring next to FIG. 2C, an individual BS device 120 within the in-tier BS region 104 may be formed to have a configuration A₃ wherein an individual vertical position (e.g., in the Z-direction) within the individual BS device 120 includes multiple transistors 122 horizontally neighboring one another (e.g., in the Y-direction), and each of the transistors 122 has a G2S configuration. Such a configuration A₃ for the BS device 120 may be considered a “multiple G2S” (mG2S) configuration. As a non-limiting example, as shown in FIG. 2C, four (4) portions of a gate electrode material 130 (effectively serving as four (4) gate electrodes) of the BS device 120 may horizontally neighbor three (3) stacks of semiconductor structures 128, such that the portions of the gate electrode material 130 horizontally alternate with the stacks of semiconductor structures 128. Two (2) surfaces (e.g., two side surfaces opposing one another in the Y-direction) of each semiconductor structure 128 of an individual stack of the semiconductor structures 128 may be horizontally neighbored (e.g., in the Y-direction) by two (2) of the four (4) portions of the gate electrode material 130. In addition, for each semiconductor structure 128 of an individual stack of the semiconductor structures 128, two (2) portions of a gate dielectric material 132 may be horizontally interposed between the semiconductor structure 128 and the two (2) portions of the gate electrode material 130. Moreover, the insulative material 112 of the tiers 114 (FIG. 1) of the stack structure 108 (FIG. 1) may be interposed between vertically neighboring semiconductor structures 128 of each of the stacks of the semiconductor structures 128. The insulative material 112 may vertically extend (e.g., in the Z-direction) from and between vertically neighboring semiconductor structures 128 of each of the stacks of the semiconductor structures 128, and may horizontally extend (e.g., in the Y-direction) from and between the horizontally neighboring pairs of the four (4) portions of the gate electrode material 130.

An individual transistor 122 for the configuration A₃ of the BS device 120 shown in FIG. 2C may be considered a G2S transistor, and may include an individual semiconductor structure 128 defining a first source/drain region, a second source/drain region, and a channel region horizontally interposed (e.g., in the X-direction) between the first source/drain region and the second source/drain region (described in further detail below with reference to FIG. 3A); two (2) portions of the gate dielectric material 132 horizontally adjacent (e.g., in the Y-direction) two (2) side surfaces of the semiconductor structure 128; and parts of the two (2) of the four (4) portions of the gate electrode material 130 horizontally adjacent (e.g., in the Y-direction) the two (2) portions of the gate dielectric material 132. Within the configuration A₃ shown in FIG. 2C, two (2) of the four (4) portions of the gate electrode material 130 may be shared by (e.g., may be common to) respective ones of the transistors 122 of the BS device 120.

In FIG. 2C, the BS device 120 is depicted as including three (3) of the transistors 122 (e.g., G2S transistors) at each vertical position (e.g., level, elevation) thereof including some of the transistors 122. However, the disclosure is not so limited, and a BS device 120 including the configuration A₃ (mG2S configuration) may be formed to include less than three (3) (e.g., two (2)) of the transistors 122 (e.g., G2S transistors) at each vertical position (e.g., level, elevation) thereof including some of the transistors 122; or may be formed to include more than three (3) (e.g., four (4), five (5), more than five (5)) of the transistors 122 at each vertical position (e.g., level, elevation) thereof including some of the transistors 122. If, for example, the BS device 120 is formed to include two (2) of the transistors 122 at each vertical position thereof including some of the transistors 122, the BS device 120 may include three (3) portions of the gate electrode material 130 horizontally alternating (e.g., in the Y-direction) with two (2) stacks of the semiconductor structures 128.

Referring next to FIG. 2D, an individual BS device 120 within the in-tier BS region 104 may be formed to have a configuration A₄ wherein the transistors 122 thereof respectively have a “gate-on-one-side” (G1S) configuration. In some embodiments, an individual vertical position (e.g., in the Z-direction) within the individual BS device 120 includes multiple transistors 122 horizontally neighboring one another (e.g., in the Y-direction), and each of the transistors 122 has a G1S configuration. As a non-limiting example, as shown in FIG. 2D, three (3) portions of a gate electrode material 130 (effectively serving as three (3) gate electrodes) of the BS device 120 may horizontally neighbor two (2) groups of stacks of semiconductor structures 128. The three (3) portions of the gate electrode material 130 horizontally alternate (e.g., in the Y-direction) with the two (2) groups of stacks of semiconductor structures 128. The two (2) groups of stacks of semiconductor structures 128 may each include two (2) stacks of semiconductor structures 128, and the two (2) stacks of semiconductor structures 128 may be horizontally separated (e.g., in the Y-direction) from another by a stack of insulative structures 134 (e.g., dielectric nitride structures). The stack of insulative structures 134 may electrically isolate the two (2) stacks of semiconductor structures 128 from one another. Within an individual group of stacks of semiconductor structures 128, one (1) surface (e.g., one side surface in the Y-direction) of each semiconductor structure 128 of one (1) of the two (2) stacks may be horizontally neighbored (e.g., in the Y-direction) by one (1) of the three (3) portions of the gate electrode material 130, and another surface (e.g., an opposing side surface in the Y-direction) of the semiconductor structure 128 may be horizontally adjacent (e.g., in the Y-direction) one (1) of the insulative structures 134. In addition, within the same individual group of stacks of semiconductor structures 128, one (1) surface (e.g., one side surface in the Y-direction) of each semiconductor structure 128 of another one (1) of the two (2) stacks may be horizontally neighbored (e.g., in the Y-direction) by another one (1) of the three (3) portions of the gate electrode material 130, and another surface (e.g., an opposing side surface in the Y-direction) of the semiconductor structure 128 may be horizontally adjacent (e.g., in the Y-direction) one (1) of the insulative structures 134. Furthermore, for each semiconductor structure 128 of an individual stack of the semiconductor structures 128 (e.g., within an individual group of stacks of semiconductor structures 128), one (1) portion of a gate dielectric material 132 may be horizontally interposed (e.g., in the Y-direction) between the semiconductor structure 128 and one (1) of the three (3) portions of the gate electrode material 130. As also shown in FIG. 2D, the insulative material 112 of the tiers 114 (FIG. 1) of the stack structure 108 (FIG. 1) may be interposed between vertically neighboring semiconductor structures 128 of each of the stacks of the semiconductor structures 128, and may also be interposed between vertically neighboring insulative structures 134 of each of the stacks of the insulative structures 134. The insulative material 112 may horizontally extend (e.g., in the Y-direction) from and between horizontally neighboring pairs of the three (3) portions of the gate electrode material 130.

An individual transistor 122 for the configuration A₄ of the BS device 120 shown in FIG. 2D may be considered a G1S transistor, and may include an individual semiconductor structure 128 defining a first source/drain region, a second source/drain region, and a channel region horizontally interposed (e.g., in the X-direction) between the first source/drain region and the second source/drain region (described in further detail below with reference to FIG. 3A); one (1) portion of the gate dielectric material 132 horizontally adjacent (e.g., in the Y-direction) one (1) side surface of the semiconductor structure 128 (wherein the other side surface of the semiconductor structure 128 is horizontally adjacent one of the insulative structures 134); and a part of one (1) of the three (3) portions of the gate electrode material 130 horizontally adjacent (e.g., in the Y-direction) the one (1) portion of the gate dielectric material 132. Within the configuration A₄ shown in FIG. 2D, the transistors 122 of the BS device 120 may, respectively, be operatively with only one (1) of the three (3) portions of the gate electrode material 130. However, one (1) of the three (3) portions of the gate electrode material 130 may be shared by (e.g., may be common to) respective ones of the transistors 122 of a single (e.g., only one) stack of the transistors 122.

In FIG. 2D, the BS device 120 is depicted as including four (4) of the transistors 122 (e.g., G1S transistors) at each vertical position (e.g., level, elevation) thereof including some of the transistors 122. However, the disclosure is not so limited, and a BS device 120 including the configuration A₄ (G1S configuration) may be formed to include less than four (4) (e.g., two (2), one (1)) of the transistors 122 (e.g., G1S transistors) at each vertical position (e.g., level, elevation) thereof including at least one of the transistors 122; or may be formed to include more than four (4) (e.g., six (6), eight (8), more than eight (8)) of the transistors 122 at each vertical position (e.g., level, elevation) thereof including some of the transistors 122. If, for example, the BS device 120 is formed to include two (2) of the transistors 122 at each vertical position thereof including some of the transistors 122, the BS device 120 may include two (2) portions of the gate electrode material 130, and one (1) group of two (2) stacks of semiconductor structures 128 horizontally therebetween (e.g., in the Y-direction). One (1) stack of the insulative structures 134 may be horizontally interposed (e.g., in the Y-direction) between the two (2) stacks of semiconductor structures 128.

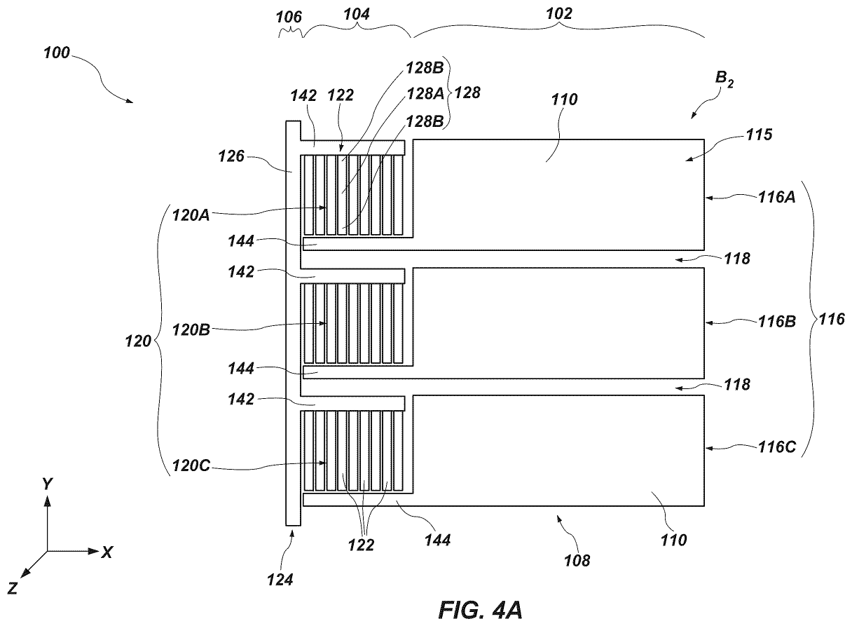

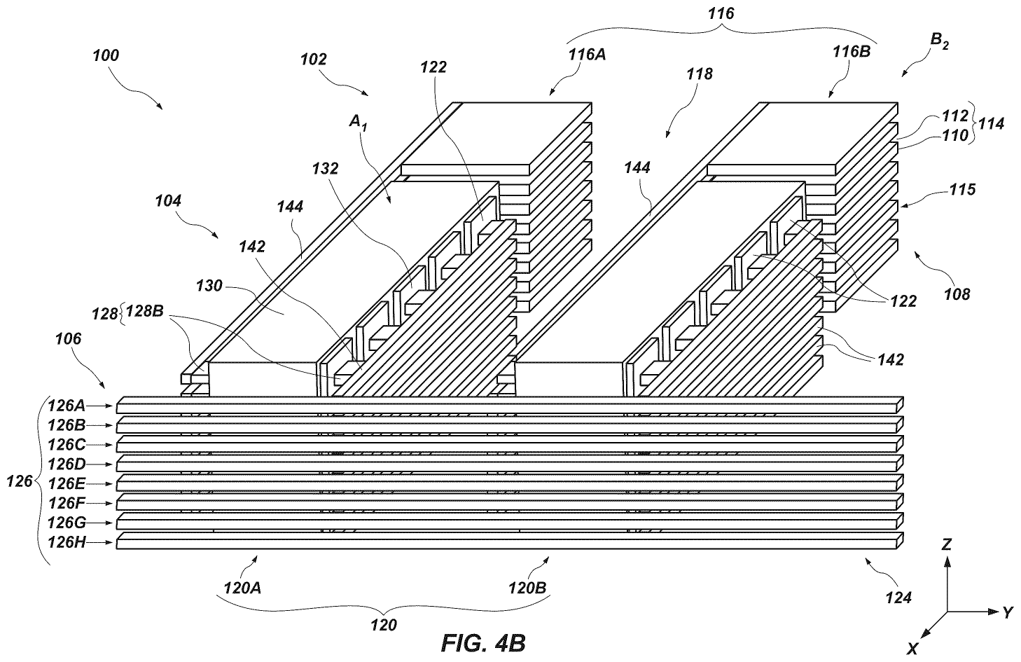

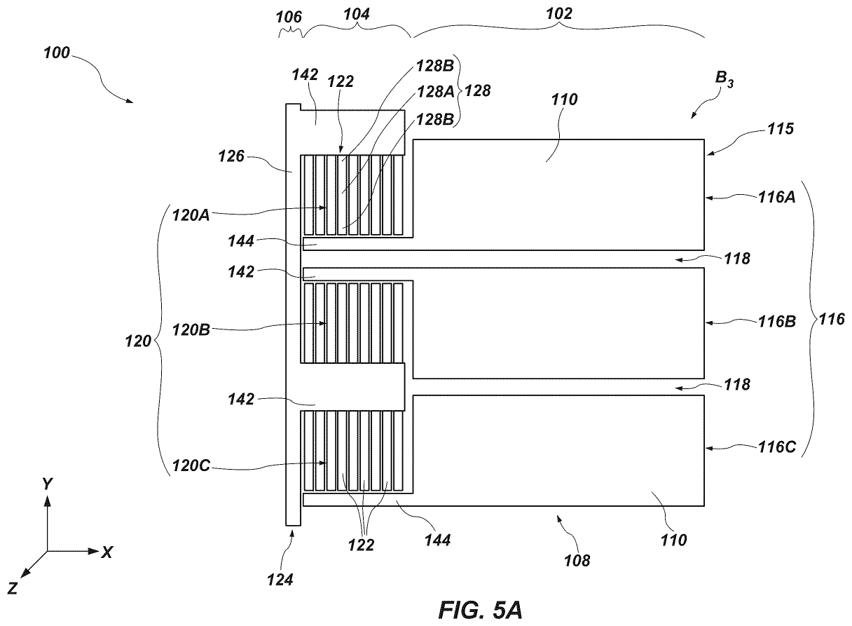

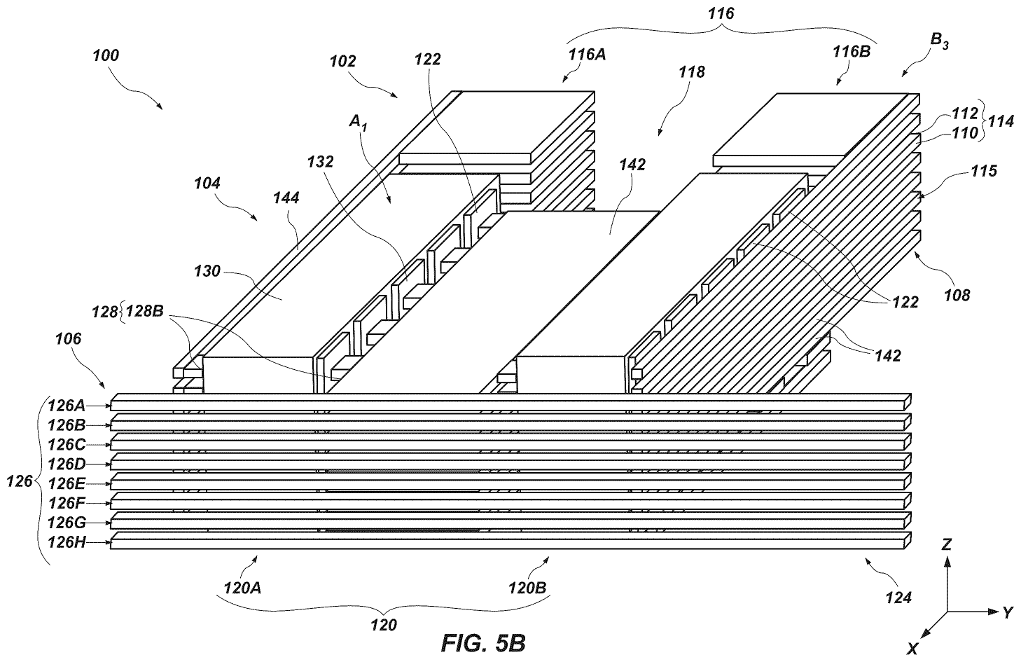

Briefly referring again to FIG. 1, in accordance with embodiments of the disclosure, the microelectronic device 100 may be formed to exhibit different configurations permitting the BS devices 120 of the in-tier BS region 104 to desirably interact (as described in further detail below) with the GWL structures 126 of the in-tier GWL region 106 and the LWL structures 115 of the blocks 116 of the block array region 102. For example, in accordance with embodiments of the disclosure, FIGS. 3A through 5D are schematic, top-down views (FIGS. 3A, 4A, and 5A) and simplified, partial-cutaway perspective views (FIGS. 3B, 4B, and 5B) of different configurations B₁ (FIGS. 3A and 3B), B₂ (FIGS. 4A and 4B), and B₃ (FIGS. 5A and 5B) that may be employed for the microelectronic device 100. It will be understood that any of the configurations B₁, B₂, and B₃ shown in FIGS. 3A through 5B, and described in further detail below, may be employed for the microelectronic device 100.

Collectively referring to FIGS. 3A and 3B, the microelectronic device 100 may be formed to have a configuration B₁ wherein the BS devices 120 (including the transistors 122 thereof) within the in-tier BS region 104 horizontally extend orthogonal to the GWL stack 124 (including the GWL structures 126 thereof) within the in-tier GWL region 106. For example, the GWL stack 124 may horizontally extend and be oriented in the Y-direction, and the BS devices 120 operatively associated with the GWL stack 124 may horizontally extend and be oriented in the X-direction orthogonal to the Y-direction. The BS devices 120 may horizontally extend, in the X-direction, from the GWL stack 124 to the blocks 116 within the block array region 102. The blocks 116 may also horizontally extend and be oriented in the X-direction.

Within an individual BS device 120 (e.g., one of the first BS device 120A, the second BS device 120B, and the third BS device 120C), the transistors 122 thereof may respectively horizontally extend, in the X-direction, from one of the GWL structures 126 of the GWL stack 124 to one of the LWL structures 115 of the one of the blocks 116 operatively associated with the BS device 120. An individual transistor 122 of the BS device 120 may be in contact, at first end thereof, with an individual GWL structure 126 vertically overlapping (e.g., in the Z-direction) the semiconductor structure 128 thereof; and may also be in contact, at second end thereof opposing the first end, with an individual LWL structure 115 vertically overlapping (e.g., in the Z-direction) the semiconductor structure 128 thereof. A first source/drain region 128B of the transistor 122, defined by and within the semiconductor structure 128, may be coupled to the GWL structure 126; a second source/drain region 128B of the transistor 122, also defined by and within the semiconductor structure 128, may be coupled to the LWL structure 115; and a channel region 128A of the transistor 122, also defined by and within the semiconductor structure 128, may be horizontally interposed (e.g., in the X-direction) between the first source/drain region 128B and the second source/drain region 128B. For each tier 114 of the stack structure 108 employed as a LWL tier, the transistors 122 of different BS devices 120 vertically overlapping the tier 114 may respectively be coupled to one of the GWL structures 126 vertically overlapping the tier 114 and one of the LWL structures 115 (as defined by a portion of the conductive material 110 of the tier 114) of one of the blocks 116 horizontally overlapping (e.g., in the Y-direction) the transistor 122.

Referring to FIG. 3B, BS generator devices 140 may be vertically offset (e.g., in the Z-direction) from and coupled to the gate electrode material 130 of the BS devices 120. An individual BS device 120 may have at least one of the BS generator devices 140 coupled thereto. In some embodiments, the BS generator devices 140 vertically underlie the BS devices 120 (and, hence, the blocks 116 and the GWL stack 124). In additional embodiments, the BS generator devices 140 vertically overlie the BS devices 120 (and, hence, the blocks 116 and the GWL stack 124). The BS generator devices 140 may be provided in various horizontal positions (e.g., in the X-direction, in the Y-direction) relative to the BS devices 120 (and, hence, the blocks 116 and the GWL stack 124), as described in further detail below. In some embodiments, an individual BS generator device 140 operatively associated with an individual BS device 120 at least partially horizontally overlaps (e.g., in the X-direction and in the Y-direction) the BS device 120. In additional embodiments, an individual BS generator device 140 operatively associated with an individual BS device 120 is horizontally offset from (e.g., in the X-direction and/or in the Y-direction) the BS device 120.

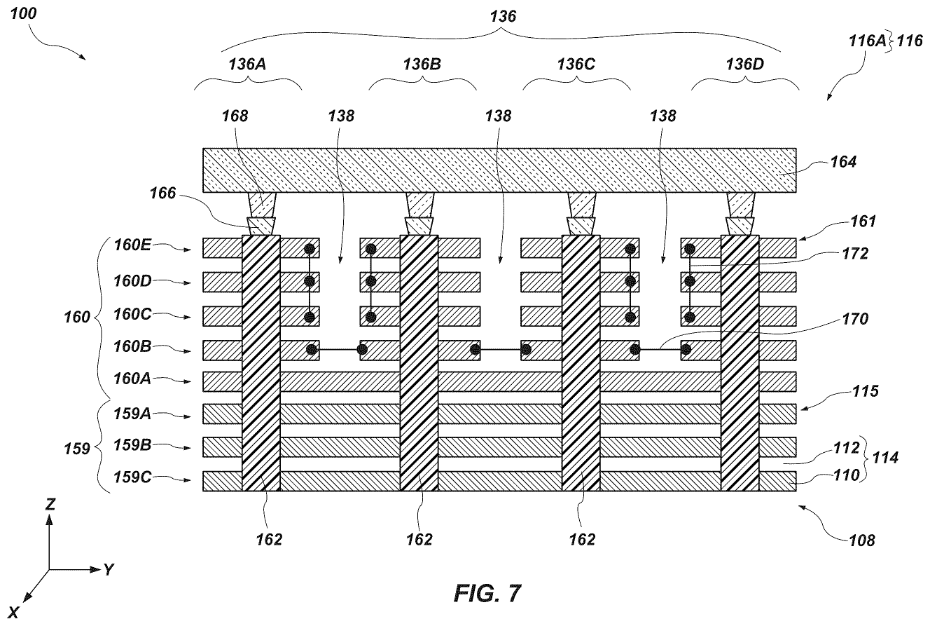

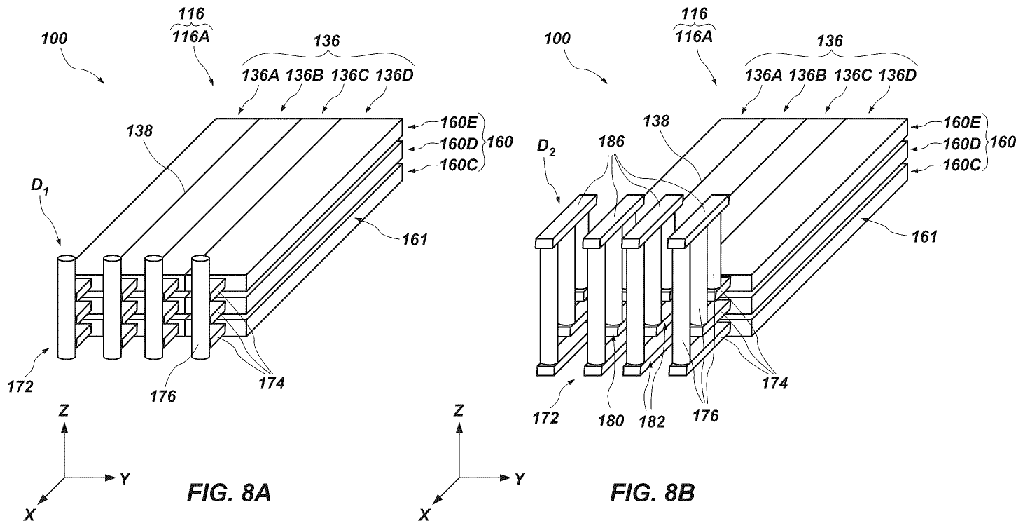

Still referring to FIG. 3B, the blocks 116 of the stack structure 108 may respectively be sub-divided into multiple sub-blocks 136. For example, an individual block 116 (e.g., the first block 116A) may be sub-divided into four (4) sub-blocks 136, such as a first sub-block 136A, a second sub-block 136B, a third sub-block 136C, and a fourth sub-block 136D. Horizontal boundaries, in the Y-direction, of the sub-blocks 136 of an individual block 116 may be at least partially defined by the insulative slot structures 118 horizontally neighboring the block 116 and additional insulative slot structures 138 positioned within a horizontal area of the block 116. The additional insulative slot structures 138 may vertically extend partially through the block 116, such as only through a vertical span of a group of the tiers 114 employed as upper select gate tiers (e.g., SGD tiers). Tiers 114 of the stack structure 108 employed as upper select gate tiers may vertically overlie (e.g., in the Z-direction) the tiers 114 of the stack structure 108 employed as LWL tiers and are described in further detail below with reference to FIGS. 7, 8A, and 8B.

FIG. 3B depicts the configuration B₁ of the microelectronic device 100 as having a multiple GAA (mGAA) form of the configuration A₁ for the BS devices 120 thereof. However, the disclosure is not so limited, and the configuration B₁ of the microelectronic device 100 may include any of the configurations A₁, A₂, A₃, and A₄ for the BS devices 120 previously described herein within reference to FIGS. 2A through 2D, respectively.

Now collectively referring to FIGS. 4A and 4B, the microelectronic device 100 may be formed to have a configuration B₂ wherein the BS devices 120 (including the transistors 122 thereof) within the in-tier BS region 104 horizontally extend parallel to the GWL stack 124 (including the GWL structures 126 thereof) within the in-tier GWL region 106. For example, the GWL stack 124 may horizontally extend and be oriented in the Y-direction, and the BS devices 120 operatively associated with the GWL stack 124 may also horizontally extend and be oriented in the Y-direction. The BS devices 120 may horizontally extend, in the Y-direction, from projections 142 (e.g., extensions, in the X-direction) of the GWL structures 126 of the GWL stack 124 to additional projections 144 (e.g., additional extensions, in the X-direction) of the LWL structures 115 of the blocks 116. The blocks 116 may also horizontally extend and be oriented in the X-direction orthogonal to the Y-direction.

The projections 142 of the GWL structures 126 may respectively horizontally extend, in the X-direction, from the in-tier GWL region 106 into the in-tier BS region 104 of the microelectronic device 100. The projections 142 of the GWL structures 126 may horizontally overlap, in the X-direction, the BS devices 120 within the in-tier BS region 104. Each of the GWL structures 126 of the GWL stack 124 may include multiple projections 142 horizontally extending therefrom, and each of the multiple projections 142 may be operatively associated with a different one of the BS devices 120 within the in-tier BS region 104 than each other of the multiple projections 142. For an individual GWL structure 126, a quantity of the projections 142 thereof may be greater than or equal to a quantity of the BS devices 120 operatively associated with the GWL structure 126. In some embodiments, each of the GWL structures 126 has a quantity of the projections 142 thereof that is the same as (e.g., equal to) a quantity of the BS devices 120 operatively associated with the GWL structure 126. For example, as shown in FIG. 4A, if an individual GWL structure 126 of the GWL stack 124 is operatively associated with three (3) BS devices 120, the GWL structure 126 may include three (3) projections 142, wherein each of the three (3) projections 142 is operatively associated with a different one (1) of the three (3) BS devices 120 than each of other of the three (3) projections 142.

The additional projections 144 of the LWL structures 115 of the blocks 116 may respectively horizontally extend, in the X-direction, from the block array region 102 into the in-tier BS region 104 of the microelectronic device 100. The additional projections 144 of the LWL structures 115 may horizontally overlap, in the X-direction, the BS devices 120 within the in-tier BS region 104. Each of the LWL structure 115 of an individual block 116 may include one (1) additional projection 144 horizontally extending therefrom, and the additional projection 144 may be operatively associated with one (1) of the BS devices 120 within the in-tier BS region 104. For example, as shown in FIG. 4A, an individual LWL structure 115 of an individual block 116 may be operatively associated with one (1) BS device 120, and the LWL structure 115 may include only one (1) additional projection 144 operatively associated with the one (1) BS device 120. As shown in FIGS. 4A and 4B, the additional projections 144 of the LWL structures 115 of the blocks 116 may horizontally alternate, in the Y-direction, with the projections 142 of the GWL structures 126.

Within an individual BS device 120 (e.g., one of the first BS device 120A and the second BS device 120B shown in FIGS. 4A and 4B), the transistors 122 thereof may respectively horizontally extend, in the Y-direction, from one of the projections 142 of one of the GWL structures 126 of the GWL stack 124 to one of the LWL structures 115 of the one of the blocks 116 operatively associated with the BS device 120. An individual transistor 122 of the BS device 120 may be in contact, at first end thereof, with an individual projection 142 of an individual GWL structure 126 vertically overlapping (e.g., in the Z-direction) the semiconductor structure 128 thereof; and may also be in contact, at second end thereof opposing the first end, with an individual additional projection 144 of an individual LWL structure 115 vertically overlapping (e.g., in the Z-direction) the semiconductor structure 128 thereof. A first source/drain region 128B of the transistor 122, defined by and within the semiconductor structure 128, may be coupled to the projection 142 of the GWL structure 126; a second source/drain region 128B of the transistor 122, also defined by and within the semiconductor structure 128, may be coupled to the additional projection 144 of the LWL structure 115; and a channel region 128A of the transistor 122, also defined by and within the semiconductor structure 128, may be horizontally interposed (e.g., in the Y-direction) between the first source/drain region 128B and the second source/drain region 128B. For each tier 114 of the stack structure 108 employed as a LWL tier, the transistors 122 of different BS devices 120 vertically overlapping the tier 114 may respectively be coupled to one of the GWL structures 126 (by way of one of the projections 142 thereof) vertically overlapping the tier 114 and one of the LWL structures 115 (by way of the additional projection 144 thereof) of one of the blocks 116 horizontally overlapping (e.g., in the Y-direction) the transistor 122.

While, for clarity and ease of understanding the drawings and related description, FIGS. 4A and 4B do not depict some of the features of the microelectronic device 100 previously described with reference configuration B₁ shown in FIGS. 3A and 3B, it will be understood that such features may be present within the configuration B₂ of the microelectronic device 100 of FIGS. 4A and 4B. For example, the configuration B₂ of the microelectronic device 100 of FIGS. 4A and 4B may also include BS generator devices 140 (FIG. 3B), sub-blocks 136 (FIG. 3B), and additional insulative slot structures 138 (FIG. 3B). In addition, while FIG. 4B depicts the configuration B₂ of the microelectronic device 100 as having the configuration A₁ for the BS devices 120 thereof, the disclosure is not so limited. The configuration B₂ of the microelectronic device 100 may include any of the configurations A₁, A₂, A₃, and A₄ for the BS devices 120 previously described herein within reference to FIGS. 2A through 2D, respectively.

Now collectively referring to FIGS. 5A and 5B, the microelectronic device 100 may be formed to have a configuration B₃ wherein the BS devices 120 (including the transistors 122 thereof) within the in-tier BS region 104 horizontally extend (e.g., in the X-direction) parallel to the GWL stack 124 (including the GWL structures 126 thereof) within the in-tier GWL region 106, but wherein projections 142 of the GWL structures 126 of the GWL stack 124 are respectively shared by (e.g., common to) two (2) of the BS devices 120 horizontally neighboring one another (e.g., in the Y-direction). For example, one BS device 120 of the two (2) BS devices 120 may horizontally extend in the Y-direction from a group of the projections 142 horizontally interposed in the Y-direction between the two (2) BS devices 120 to additional projections 144 of the LWL structures 115 of one block 116 of the two (2) blocks 116; and the other BS device 120 of the two (2) BS devices 120 may horizontally extend in the Y-direction from the group of the projections 142 to additional projections 144 of the LWL structures 115 of the other one of the two (2) blocks 116. The blocks 116 may horizontally extend and be oriented in the X-direction orthogonal to the Y-direction.

The projections 142 of the GWL structures 126 may respectively horizontally extend, in the X-direction, from the in-tier GWL region 106 into the in-tier BS region 104 of the microelectronic device 100. The projections 142 of the GWL structures 126 may horizontally overlap, in the X-direction, the BS devices 120 within the in-tier BS region 104. Each of the GWL structures 126 of the GWL stack 124 may include multiple projections 142 horizontally extending therefrom, and each of the multiple projections 142 may be operatively associated with two (2) of the BS devices 120 within the in-tier BS region 104. For an individual GWL structure 126, a quantity of the projections 142 thereof may be less than a quantity of the BS devices 120 operatively associated with the GWL structure 126. In some embodiments wherein the in-tier BS region 104 includes an even number of the BS devices 120 operatively associated with the GWL stack 124, each of the GWL structures 126 of the GWL stack 124 has a quantity of the projections 142 thereof equal to one-half (0.5X) of a quantity of the BS devices 120 operatively associated with the GWL structure 126. For example, as shown in FIG. 5B, if an individual GWL structure 126 of the GWL stack 124 is operatively associated with two (2) BS devices 120 (e.g., the first BS device 120A and the second BS device 120B), the GWL structure 126 may include one (1) projection 142, wherein the one (1) projection 142 is operatively associated with (e.g., shared by) both of the two (2) BS devices 120. In additional embodiments wherein the in-tier BS region 104 includes an odd number of the BS devices 120 operatively associated with the GWL stack 124, each of the GWL structures 126 of the GWL stack 124 has a quantity of the projections 142 thereof equal to two-thirds (0.66X) of a quantity of the BS devices 120 operatively associated with the GWL structure 126.

The additional projections 144 of the LWL structures 115 of the blocks 116 may respectively horizontally extend, in the X-direction, from the block array region 102 into the in-tier BS region 104 of the microelectronic device 100. The additional projections 144 of the LWL structures 115 may horizontally overlap, in the X-direction, the BS devices 120 within the in-tier BS region 104. Each of the LWL structures 115 of an individual block 116 may include one (1) additional projection 144 horizontally extending therefrom, and the additional projection 144 may be operatively associated with one (1) of the BS devices 120 within the in-tier BS region 104. For example, as shown in FIG. 5A, an individual LWL structure 115 of an individual block 116 may be operatively associated with one (1) BS device 120, and the LWL structure 115 may include only one (1) additional projection 144 operatively associated with the one (1) BS device 120. As shown in FIGS. 5A and 5B, the additional projections 144 of the LWL structures 115 of the blocks 116 may horizontally alternate, in the Y-direction, with the projections 142 of the GWL structures 126.

Within an individual BS device 120 (e.g., one of the first BS device 120A and the second BS device 120B shown in FIGS. 4A and 4B), the transistors 122 thereof may respectively horizontally extend, in the Y-direction, from one of the projections 142 of one of the GWL structures 126 of the GWL stack 124 to one of the LWL structures 115 of the one of the blocks 116 operatively associated with the BS device 120. An individual transistor 122 of the BS device 120 may be in contact, at first end thereof, with an individual projection 142 of an individual GWL structure 126 vertically overlapping (e.g., in the Z-direction) the semiconductor structure 128 thereof; and may also be in contact, at second end thereof opposing the first end, with an individual additional projection 144 of an individual LWL structure 115 vertically overlapping (e.g., in the Z-direction) the semiconductor structure 128 thereof. A first source/drain region 128B of the transistor 122, defined by and within the semiconductor structure 128, may be coupled to the projection 142 of the GWL structure 126; a second source/drain region 128B of the transistor 122, also defined by and within the semiconductor structure 128, may be coupled to the additional projection 144 of the LWL structure 115; and a channel region 128A of the transistor 122, also defined by and within the semiconductor structure 128, may be horizontally interposed (e.g., in the Y-direction) between the first source/drain region 128B and the second source/drain region 128B. For each tier 114 of the stack structure 108 employed as a LWL tier, the transistors 122 of different BS devices 120 vertically overlapping the tier 114 may respectively be coupled to one of the GWL structures 126 (by way of one of the projections 142 thereof) vertically overlapping the tier 114 and one of the LWL structures 115 (by way of the additional projection 144 thereof) of one of the blocks 116 horizontally overlapping (e.g., in the Y-direction) the transistor 122.

While, for clarity and ease of understanding the drawings and related description, FIGS. 5A and 5B do not depict some of the features of the microelectronic device 100 previously described with reference configuration B₁ shown in FIGS. 3A and 3B, it will be understood that such features may be present within the configuration B₃ of the microelectronic device 100 of FIGS. 5A and 5B. For example, the configuration B₃ of the microelectronic device 100 of FIGS. 5A and 5B may also include BS generator devices 140 (FIG. 3B), sub-block 136 (FIG. 3B), and additional insulative slot structures 138 (FIG. 3B). In addition, while FIG. 5B depicts the configuration B₃ of the microelectronic device 100 as having the configuration A₁ for the BS devices 120 thereof, the disclosure is not so limited. The configuration B₃ of the microelectronic device 100 may include any of the configurations A₁, A₂, A₃, and A₄ for the BS devices 120 previously described herein within reference to FIGS. 2A through 2D, respectively.

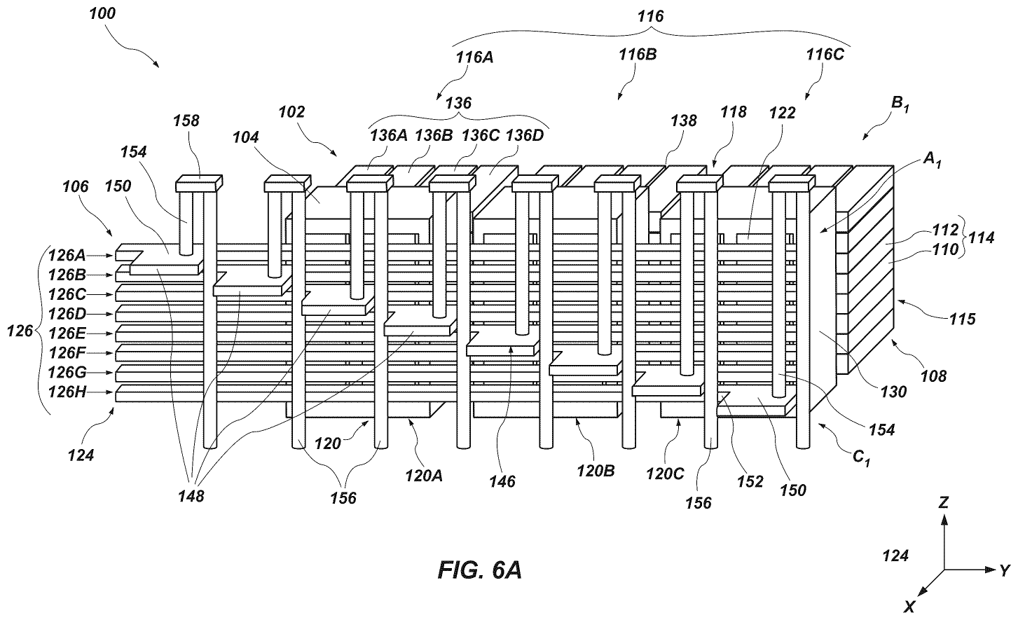

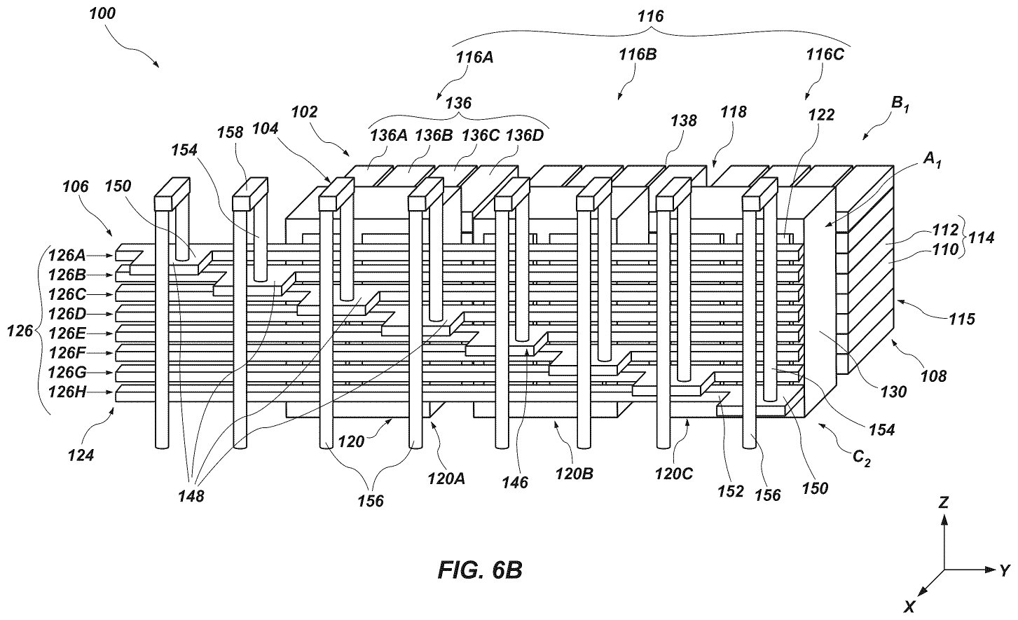

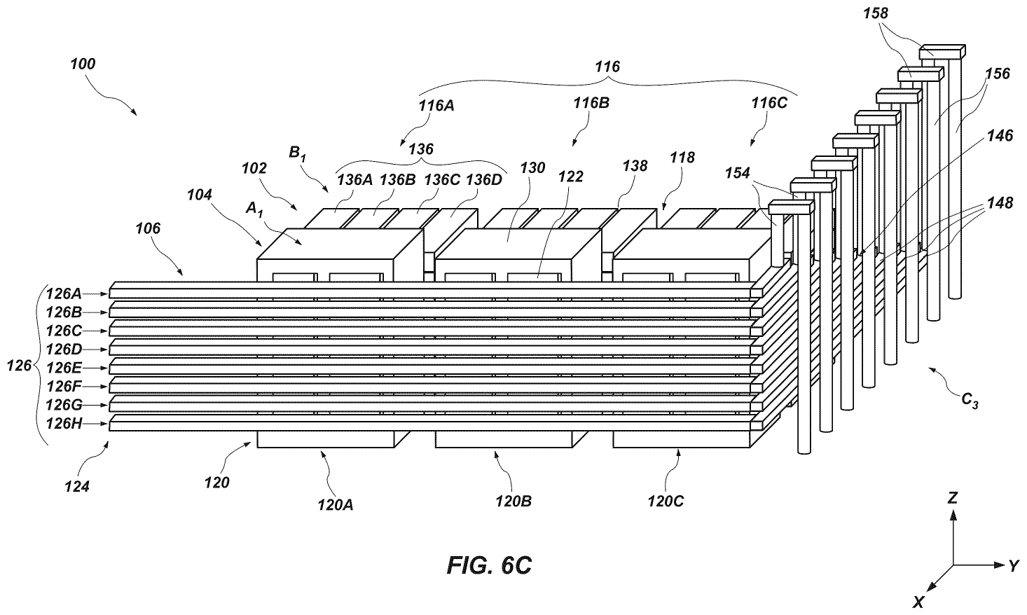

Briefly referring again to FIG. 1, in accordance with embodiments of the disclosure, the microelectronic device 100 may be formed to include a staircase structure for the GWL stack 124, wherein steps of the staircase structure define contact regions for the GWL structures 126 of the GWL stack 124. In addition, the microelectronic device 100 may further include conductive interconnect assemblies (e.g., including conductive contacts and conductive routing) coupled to the steps of the staircase structure. For example, in accordance with embodiments of the disclosure, FIGS. 6A through 6C are simplified, partial-cutaway perspective views of different configurations C₁ (FIG. 6A), C₂ (FIG. 6B), and C₃ (FIG. 6C) that may be employed for an individual GWL staircase region of the microelectronic device 100.

Referring to FIG. 6A, a configuration C₁ for a GWL staircase region of the microelectronic device 100 may include a GWL staircase structure 146 positioned within the in-tier GWL region 106 of the microelectronic device 100. The GWL staircase structure 146 may include steps 148 formed from further projections 150 of the GWL structures 126 of the GWL stack 124. Each of the GWL structures 126 may include an individual further projection 150 positioned within in-tier GWL region 106 and defining an individual step 148 of the GWL staircase structure 146. Steps 148 of the GWL staircase structure 146 (as defined by the projections 150 of the GWL structures 126) horizontally neighboring one another in the Y-direction may be horizontally offset from one another in the Y-direction by step separation regions 152. The step separation regions 152 may horizontally alternate with the steps 148 of the GWL staircase structure 146 in the Y-direction. The step separation regions 152 may prevent steps 148 vertically neighboring one another in the Z-direction from horizontally overlapping one another in the Y-direction.

Still referring to FIG. 6A, first GWL contact structures 154, second GWL contact structures 156, and GWL routing structures 158 may be positioned within the in-tier GWL region 106 of the microelectronic device 100 and may be operatively associated with the GWL staircase structure 146. The first GWL contact structures 154, the second GWL contact structures 156, and the GWL routing structures 158 may, in combination, couple the GWL staircase structure 146 (and, hence, the GWL structures 126 of the GWL stack 124) to control logic circuitry (e.g., GWL driver devices, GWL generator devices) vertically offset from (e.g., vertically underlying) the GWL staircase structure 146.

The first GWL contact structures 154 may be positioned within horizontal areas of and may physically contact (e.g., land on) the steps 148 of the GWL staircase structure 146. An individual first GWL contact structure 154 has a lower end in physical contact with an individual step 148 of the GWL staircase structure 146, and an upper end in physical contact with an individual GWL routing structure 158. The first GWL contact structures 154 may individually be formed of and include conductive material. In some embodiments, the first GWL contact structures 154 are individually formed of and include one or more of W, Ru, Mo, TiN.

The second GWL contact structures 156 may be positioned within horizontal areas of and may vertically extend through the step separation regions 152. An individual second GWL contact structure 156 may be horizontally interposed, in the Y-direction, between two (2) of the steps 148 of the GWL staircase structure 146 horizontally neighboring one another in the Y-direction. As shown in FIG. 6A, an individual second GWL contact structure 156 have a lower end that vertically underlies the blocks 116 of the stack structure 108 (and, hence, the BS devices 120 and the GWL stack 124), and an upper end in physical contact with an individual GWL routing structure 158. The second GWL contact structures 156 may individually be formed of and include conductive material. In some embodiments, the second GWL contact structures 156 are individually formed of and includes one or more of W, Ru, Mo, TiN.

The GWL routing structures 158 may vertically overlie and couple individual first GWL contact structures 154 to individual second GWL contact structures 156. As shown in FIG. 6A, the GWL routing structures 158 may be located at substantially the same vertical position (e.g., vertical elevation) as one another. An individual GWL routing structure 158 may horizontally extend, in the Y-direction, from an individual first GWL contact structure 154 to an individual second GWL contact structure 156. The GWL routing structures 158 may individually be formed of and include conductive material. In some embodiments, the GWL routing structures 158 are individually formed of and includes one or more of W, Ru, Mo, TiN.

The configuration C₁ for the GWL staircase region of the microelectronic device 100 shown in FIG. 6A may, for example, permit the GWL staircase structure 146, the first GWL contact structures 154, the second GWL contact structures 156, and the GWL routing structures 158 to respectively be horizontally positioned, in the X-direction, at the edge (e.g., horizontal end) of a plane of the blocks 116, between two (2) groups (e.g., two (2) half planes) of a plane of the blocks 116, or between two planes of the blocks 116. Such options are described in further detail below.

Referring next to FIG. 6B, a configuration C₂ for a GWL staircase region of the microelectronic device 100 may also include a GWL staircase structure 146 (including steps 148 thereof and associated step separation regions 152) positioned within the in-tier GWL region 106 of the microelectronic device 100, in substantially the same manner as previously described herein for the configuration C₁ of FIG. 6A. However, in the configuration C₂ of FIG. 6B, the horizontal positions of the second GWL contact structures 156 are different than those in the configuration C₁ of FIG. 6A. Namely, rather than being positioned within the horizontal areas of step separation regions 152, the second GWL contact structures 156 may be positioned within horizontal spans of the steps 148 in the Y-direction and may be horizontally offset from the steps 148 in the X-direction. An individual second GWL contact structure 156 may horizontally overlap an individual step 148 of the GWL staircase structure 146 in the Y-direction, but may be horizontally spaced apart from the step 148 in the X-direction. As a result, the GWL routing structures 158 may respectively be oriented in the X-direction. An individual GWL routing structure 158 may horizontally extend, in the X-direction, from an individual first GWL contact structure 154 (located on an individual step 148 of the GWL staircase structure 146) to an individual second GWL contact structure 156. The configuration C₂ of FIG. 6B may, for example, permit the GWL staircase structure 146, the first GWL contact structures 154, the second GWL contact structures 156, and the GWL routing structures 158 to respectively be horizontally positioned, in the X-direction, at the edge (e.g., horizontal end) of a plane of the blocks 116.

Referring next to FIG. 6C, a configuration C₃ for a GWL staircase region of the microelectronic device 100 may include a GWL staircase structure 146 positioned outside of the in-tier GWL region 106 of the microelectronic device 100. For example, the GWL staircase structure 146 may be positioned within horizontal spans of the in-tier BS region 104 and the block array region 102 of the microelectronic device 100. The GWL staircase structure 146 may horizontally extend in the X-direction proximate a side (e.g., horizontal end) of a horizontally outermost one of the blocks 116 in the Y-direction. A portion of GWL stack 124 may be positioned within the in-tier GWL region 106 and may horizontally extend in the Y-direction. However, an additional portion of the GWL stack 124 may horizontally extend in the X-direction proximate the side of the horizontally outermost one of the blocks 116 in the Y-direction, and may define the GWL staircase structure 146. As shown in FIG. 6C, edges (e.g., horizontal ends) of portions of the GWL structures 126 within the additional portion of the GWL stack 124 may define the steps 148 of the GWL staircase structure 146.

The first GWL contact structures 154 may be positioned within horizontal areas of and may physically contact (e.g., land on) the steps 148 of the GWL staircase structure 146. The second GWL contact structures 156 may be within horizontal spans of the steps 148 in the X-direction, and may be horizontally offset from the steps 148 in the Y-direction. An individual second GWL contact structure 156 may horizontally overlap an individual step 148 of the GWL staircase structure 146 in the X-direction, but may be horizontally offset from the step 148 of the GWL staircase structure 146 in the Y-direction. The GWL routing structures 158 may respectively be oriented in the Y-direction. An individual GWL routing structure 158 may horizontally extend, in the Y-direction, from an individual first GWL contact structure 154 (located on an individual step 148 of the GWL staircase structure 146) to an individual second GWL contact structure 156.

The configuration C₃ of FIG. 6C may, for example, permit the GWL staircase structure 146, the first GWL contact structures 154, the second GWL contact structures 156, and the GWL routing structures 158 to respectively be horizontally positioned, in the Y-direction, proximate a side (e.g., horizontal end in the Y-direction) of a plane of the blocks 116.

Referring next to FIG. 7, depicted is a simplified, vertical cross-sectional view of a portion of the microelectronic device 100 encompassing an upper select gate region (e.g., an SGD region) of an individual block 116 of the microelectronic device 100. As shown in FIG. 7, an upper group of the tiers 114 of the stack structure 108 may be employed as SGD tiers 160. The SGD tiers 160 may vertically overlie (e.g., in the Z-direction) a relatively lower group of the tiers 114 of the stack structure 108 employed as LWL tiers 159. By way of non-limiting example, the LWL tiers 159 may include a first LWL tier 159A, a second LWL tier 159B vertically underlying the first LWL tier 159A, and a third LWL tier 159C vertically underlying the second LWL tier 159B; and the SGD tiers 160 may include a first SGD tier 160A vertically overlying the first LWL tier 159A, a second SGD tier 160B vertically underlying the first SGD tier 160A, a third SGD tier 160C vertically underlying the second SGD tier 160B, a fourth SGD tier 160D vertically underlying the third SGD tier 160C, and a fifth SGD tier 160E vertically underlying the fourth SGD tier 160D.

As previously described herein, within an individual block 116 (e.g., the first block 116A) of the stack structure 108, the conductive material 110 of the tiers 114 utilized as LWL tiers 159 may be employed for and define the LWL structures 115 of the block 116. Similarly, within the block 116, the conductive material 110 of the tiers 114 utilized as SGD tiers 160 may be employed for and define SGD structures 161 of the block 116. Within the block 116, the additional insulative slot structures 138 may partition the conductive material 110 of some of the SGD tiers 160 (e.g., relatively higher ones of the SGD tiers 160, such as the fifth SGD tier 160E, the fourth SGD tier 160D, the third SGD tier 160C, and the second SGD tier 160B). As a result, within a horizontal area of the block 116, these SGD tiers 160 may respectively include multiple SGD structures 161. For example, as shown in FIG. 7, within an individual block 116, the fifth SGD tier 160E, the fourth SGD tier 160D, the third SGD tier 160C, and the second SGD tier 160B may respectively include four (4) SGD structures 161, one for each of the four (4) sub-blocks 136 (e.g., the first sub-block 136A, the second sub-block 136B, the third sub-block 136C, and the fourth sub-block 136D) of the block 116. In addition, within the block 116, the conductive material 110 of one or more others of the SGD tiers 160 (e.g., at least one relatively lower one of the SGD tiers 160, such as the first SGD tier 160A) may not be partitioned by the additional insulative slot structures 138. As a result, within a horizontal area of the block 116, such SGD tiers 160 may respectively include a single (e.g., only one) SGD structure 161.

For an individual block 116, SGD functions for some of the SGD tiers 160 (e.g., relatively lower ones of the SGD tiers 160, such as the first SGD tier 160A and the second SGD tier 160B) may be controlled, in-part, by and utilize the GWL stack 124 (FIG. 1) and the BS devices 120 (FIG. 1) (including the associated levels of transistors 122 (FIG. 1) thereof) in a manner similar to that previously described herein in relation to the LWL structures 115 of the LWL tiers 159. In this regard, as shown in FIG. 7, if the conductive material 110 of any such an individual SGD tier 160 (e.g., the second SGD tier 160B) is partitioned by the additional insulative slot structures 138, first SGD routing structures 170 may be employed to couple the multiple (e.g., four) SGD structures 161 of the SGD tier 160 to one another.

In addition, for an individual block 116, SGD functions for some others of the SGD tiers 160 (e.g., relatively higher ones of the SGD tiers 160, such as the third SGD tier 160C, the fourth SGD tier 160D, and the fifth SGD tier 160E) may be controlled, in-part, by and utilize different features (e.g., structures, circuitry, devices) of the microelectronic device 100 than some of the SGD tiers 160 (e.g., the relatively lower ones of the SGD tiers 160, such as the first SGD tier 160A and the second SGD tier 160B). For example, the SGD structures 161 of the third SGD tier 160C, the fourth SGD tier 160D, and the fifth SGD tier 160E may be operatively associated with control logic circuitry vertically offset from (e.g., vertically above) the stack structure 108 without utilizing the GWL stack 124 (FIG. 1) and the BS devices 120 (FIG. 1) previously described herein. In this regard, as shown in FIG. 7, for individual sub-blocks 136 of the block 116, the SGD structures 161 thereof of different SGD tiers 160 may be ganged together by second SGD routing structures 172. As a non-limiting example, three (3) SGD structures 161 of the third SGD tier 160C, the fourth SGD tier 160D, and the fifth SGD tier 160E within the first sub-block 136A of the block 116 may be ganged together by some of the second SGD routing structures 172; and three (3) more SGD structures 161 of the third SGD tier 160C, the fourth SGD tier 160D, and the fifth SGD tier 160E within the second sub-block 136B of the block 116 may be ganged together by some others of the second SGD routing structures 172. Different configurations that may be employed for the second SGD routing structures 172 to facilitate the aforementioned ganging of the SGD structures 161 are described in further detail below with reference to FIGS. 8A and 8B.

Before referring to FIGS. 8A and 8B, other features of the microelectronic device 100 depicted in FIG. 7 include cell pillar structures 162, digit line structures 164, plug structures 166, and digit line contact structures 168. As shown in FIG. 7, the cell pillar structures 162 may vertically extend through the tiers 114 of the stack structure 108 and may be positioned within horizontal areas of the sub-blocks 136 of the respective blocks 116 of the stack structure 108. The cell pillar structures 162 correspond to the cell pillar structures previously described herein with reference to FIG. 1, and define vertically extending strings of memory cells at intersections of the cell pillar structures 162 and the LWL structures 115 of the block 116. The digit line structures 164 may vertically overlie (e.g., in the Z-direction) and horizontally extend across (e.g., in the Y-direction) the stack structure 108 and may be coupled to the cell pillar structures 162 (and, hence, the vertically extending strings of memory cells) of the blocks 116 by way of the plug structures 166 and the digit line contact structures 168. The plug structures 166 may vertically overlie and may be coupled to the cell pillar structures 162, and the digit line contact structures 168 may be vertically interposed between and coupled to the plug structures 166 and the digit line structures 164. The digit line structures 164, the plug structures 166, and the digit line contact structures 168 may respectively be formed of and include conductive material.

Now collectively referring to FIGS. 8A and 8B, depicted are simplified, partial-cutaway perspective views of different configurations D₁ (FIG. 8A) and D₂ (FIG. 8B) that may be employed, within the upper select gate region (e.g., SGD region) for the microelectronic device 100 described above with reference to FIG. 7, for the second SGD routing structures 172. The configurations D₁ (FIG. 8A) and D₂ (FIG. 8B) may be employed to gang together SGD structures 161 within the same sub-block 136 (e.g., the first sub-block 136A, the second sub-block 136B, the third sub-block 136C, or the fourth sub-block 136D) as one another but within different SGD tiers 160 (e.g., the fifth SGD tier 160E, the fourth SGD tier 160D, the third SGD tier 160C) than one another.

Referring to FIG. 8A, the second SGD routing structures 172 may be formed to have a configuration D₁ including horizontal SGD interconnect structures 174 and vertical SGD interconnect structures 176. For an individual sub-block 136 of an individual block 116, a single (e.g., only one) vertical SGD interconnect structure 176 may be horizontally offset, in the X-direction, from the SGD structures 161 of different SGD tiers 160 (e.g., the fifth SGD tier 160E, the fourth SGD tier 160D, the third SGD tier 160C), and may horizontally overlap the SGD structures 161 in the Y-direction. Furthermore, a group of the horizontal SGD interconnect structures 174 may horizontally extend, in the X-direction, from the vertical SGD interconnect structure 176 to the SGD structures 161. If, for example, for an individual sub-block 136 (e.g., the first sub-block 136A, the second sub-block 136B, the third sub-block 136C, or the fourth sub-block 136D) three (3) SGD structures 161 are ganged together by the second SGD routing structures 172, three (3) horizontal SGD interconnect structures 174 may horizontally extend from the three (3) SGD structures 161 (e.g., one (1) for each SGD structure 161) to one (1) vertical SGD interconnect structure 176. Accordingly, the group of the horizontal SGD interconnect structures 174 may couple the different SGD structures 161 to the same vertical SGD interconnect structure 176 to effectuate the ganging of the different SGD structures 161. In the configuration D₁ of FIG. 8A, the horizontal SGD interconnect structures 174 may have substantially the same horizontal dimension (e.g., length) as one other in the X-direction. The horizontal SGD interconnect structures 174 and the vertical SGD interconnect structures 176 may respectively be formed of and include conductive material.

Referring next to FIG. 8B, the second SGD routing structures 172 may be formed to have a configuration D₂ wherein the horizontal SGD interconnect structures 174 are configured to form SGD staircase structures 180 respectively having steps 182 defined by horizontal ends of the horizontal SGD interconnect structures 174 in the X-direction. For an individual sub-block 136 (e.g., the first sub-block 136A, the second sub-block 136B, the third sub-block 136C, or the fourth sub-block 136D) of an individual block 116, a group of the horizontal SGD interconnect structures 174 may horizontally extend, in the X-direction, from the different SGD structures 161 of the different SGD tiers 160 (e.g., the fifth SGD tier 160E, the fourth SGD tier 160D, the third SGD tier 160C), and may define an individual SGD staircase structure 180 operatively associated with the different SGD structures 161. The horizontal SGD interconnect structures 174 of the group may have different horizontal dimensions (e.g., lengths) in the X-direction than one another to facilitate the steps 182 of the SGD staircase structure 180. For example, a horizontal SGD interconnect structure 174 for the third SGD tier 160C may be relatively longer in the X-direction than a different horizontal SGD interconnect structure 174 for the fourth SGD tier 160D, and the horizontal SGD interconnect structure 174 for the fourth SGD tier 160D may be relatively longer in the X-direction than a different horizontal SGD interconnect structure 174 for the fifth SGD tier 160E. Furthermore, for an individual sub-block 136, a group of the vertical SGD interconnect structures 176 may contact the group of the horizontal SGD interconnect structures 174 at the steps 182 of the SGD staircase structure 180. Each step 182 of the SGD staircase structure 180 may have one (1) of the vertical SGD interconnect structures 176 of the group of vertical SGD interconnect structures 176 in physical contact therewith. For example, if an individual SGD staircase structure 180 includes three (3) steps 182 (e.g., defined by three (3) different horizontal SGD interconnect structures 174), three (3) vertical SGD interconnect structures 176 may contact the three (3) steps 182 (one (1) vertical SGD interconnect structure 176 per step 182). Moreover, as shown in FIG. 8B, for an individual sub-block 136, an additional horizontal SGD interconnect structure 186 may vertically overlie (e.g., in the Z-direction) and horizontally extend (e.g., in the X-direction) across the group of vertical SGD interconnect structures 176. The additional horizontal SGD interconnect structure 186 may couple the vertical SGD interconnect structures 176 of one group to one another. Accordingly, for an individual sub-block 136, a group of the horizontal SGD interconnect structures 174 (e.g., defining an individual SGD staircase structure 180), a group of the vertical SGD interconnect structures 176, and an additional horizontal SGD interconnect structure 186 may couple the different SGD structures 161 of different SGD tiers 160 to one another to effectuate the ganging of the different SGD structures 161.

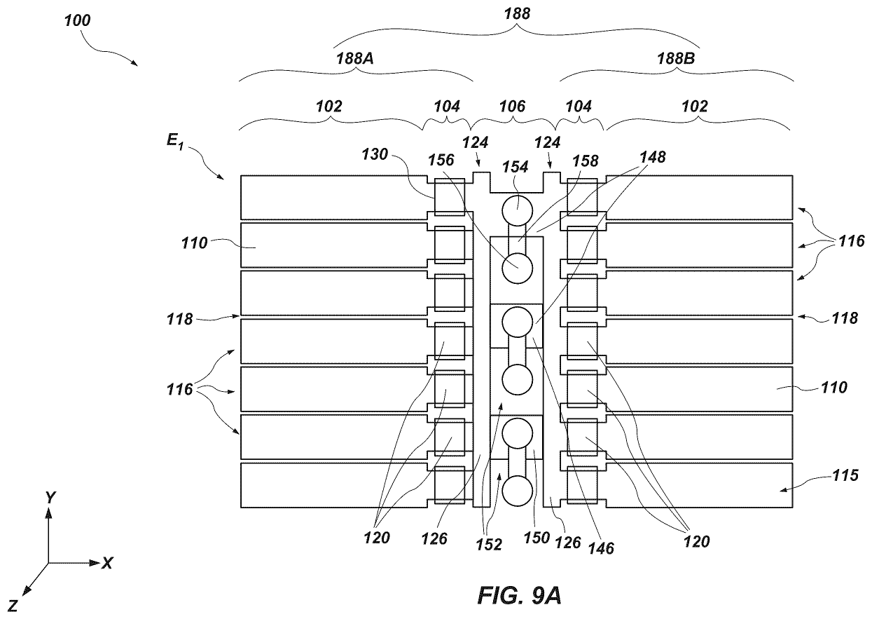

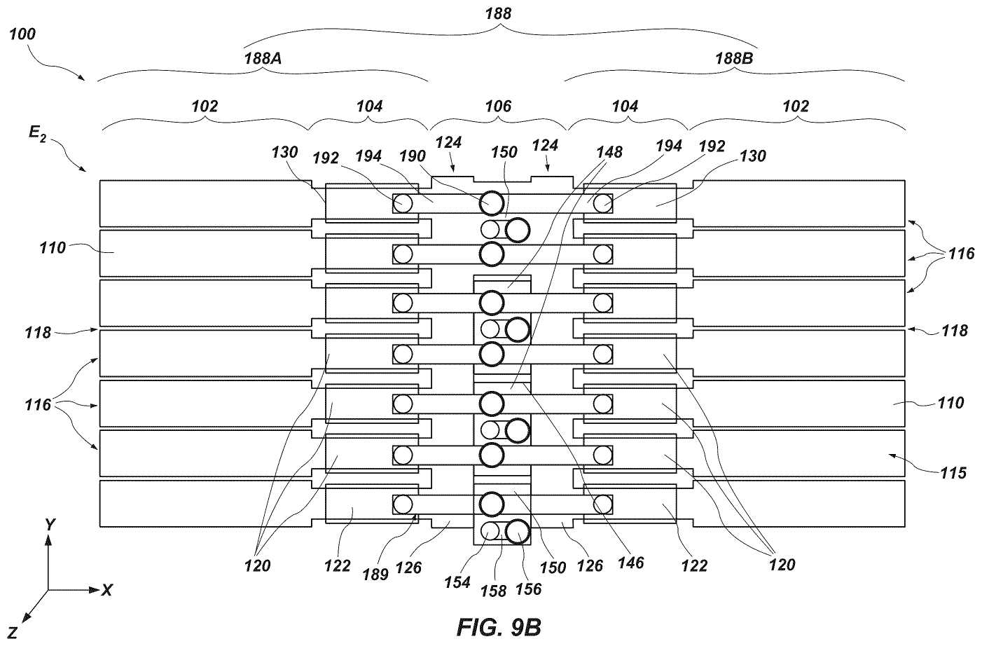

Briefly referring again to FIG. 6A, as previously described herein, the microelectronic device 100 may include multiple groups (e.g., sub-planes, planes) of the blocks 116 and multiple groups of the BS devices 120 operatively associated with the multiple groups of the blocks 116. In addition, the microelectronic device 100 may include and at least one (e.g., one, more than one) GWL staircase structure 146 operatively associated with one or more GWL stacks 124 operatively associated with the multiple groups of the blocks 116 and the multiple groups of the BS devices 120. For example, in accordance with embodiments of the disclosure, FIGS. 9A and 9B are schematic, top-down views of different configurations E₁ (FIG. 9A) and E₂ (FIG. 9B) that may be employed for the microelectronic device 100. It will be understood that any of the configurations E₁ and E₂ shown in FIGS. 9A and 9B and described in further detail below may be employed for the microelectronic device 100.

Referring to FIG. 9A, the microelectronic device 100 may be formed to have a configuration E₁ including multiple (e.g., more than one) block sections 188. The block sections 188, for example, include a first block section 188A, and a second block section 188B horizontally offset from the first block section 188A in the X-direction. The block sections 188 may individually include a block array region 102 including a group of the blocks 116, and an in-tier BS region 104 including a group of the BS devices 120 operatively associated with the group of the blocks 116. In addition, the microelectronic device 100 may include an in-tier GWL region 106 horizontal horizontally interposed between, in the X-direction, block sections 188 (e.g., the first block section 188A and the second block section 188B) horizontally neighboring one another in the X-direction. The in-tier GWL region 106 may include two (2) GWL stacks 124 that are coupled together (e.g., by way of a GWL staircase structure 146 shared therebetween) to effectively act as a single (e.g., one) GWL stack 124. One (1) of the two (2) GWL stacks 124 includes GWL structures 126 in contact with the group of the BS devices 120 of one of the block sections 188 (e.g., the first block section 188A). The other one (1) of the two (2) GWL stacks 124 includes GWL structures 126 in contact with the group of the BS devices 120 of another one of the block sections 188 (e.g., the second block section 188B). The two (2) GWL stacks 124 may share a single (e.g., only one) GWL staircase structure 146 with one another. The GWL staircase structure 146 may be positioned within a GWL staircase region horizontally interposed, in the X-direction, between the two (2) GWL stacks 124. In some embodiments, the GWL staircase region has the configuration C₁ previously described herein with reference to FIG. 6A. First GWL contact structures 154 may physically contact (e.g., land on) the steps 148 of the GWL staircase structure 146; second GWL contact structures 156 may be positioned within horizontal areas of and may vertically extend through step separation regions 152 between the steps 148; and the GWL routing structures 158 may vertically overlie and couple individual first GWL contact structures 154 to individual second GWL contact structures 156.

Referring next to FIG. 9B, the microelectronic device 100 may be formed to have a configuration E₂ having some similarities (including the multiple block sections 188, the two (2) GWL stacks 124, and the GWL staircase structure 146) of the configuration E₁ of FIG. 9A, but also including BS routing assemblies 189 coupled to the gate electrode material 130 of different BS devices 120 within the in-tier BS regions 104 of the block sections 188. The BS routing assemblies 189 may respectively include two (2) first BS contact structures 192, a second BS contact structure 190, and a BS routing structure 194. One of the two (2) first BS contact structures 192 may contact (e.g., physically contact) the gate electrode material 130 of one of the BS devices 120 within one of the block sections 188 (e.g., the first block section 188A), and another one the two (2) first BS contact structures 192 of the two (2) first BS contact structures 192 may contact (e.g., physically contact) the gate electrode material 130 of one of the BS devices 120 within one of the block sections 188 (e.g., the second block section 188B). The second BS contact structure 190 may be vertically offset from (e.g., vertically overlie) the two (2) first BS contact structures 192. The BS routing structure 194 may be vertically interposed (e.g., in the Z-direction) between the second BS contact structure 190 and the two (2) first BS contact structures 192 and may horizontally extend (e.g., in the X-direction) between and couple the second BS contact structure 190 and the two (2) first BS contact structures 192. The first BS contact structures 192, the second BS contact structures 190, and the BS routing structures 194 of the BS routing assemblies 189 may respectively be formed of and include conductive material. Isolation material (e.g., insulative material) may at least partially surround portions (e.g., the first BS contact structures 192, the second BS contact structures 190, the BS routing structures 194) of the BS routing assemblies 189.

Still referring to FIG. 9B, as compared to the configuration E₁ of FIG. 9A, the inclusion of the BS routing assemblies 189 within the configuration E₂ of FIG. 9B may result in modifications to the arrangements of the first GWL contact structures 154, the second GWL contact structures 156, and the GWL routing structures 158 within the GWL staircase region horizontally interposed (e.g., in the X-direction) between the two (2) GWL stacks 124. The first GWL contact structures 154 may physically contact (e.g., land on) the steps 148 of the GWL staircase structure 146. The second GWL contact structures 156 may be vertically offset from (e.g., vertically overlie) the first GWL contact structures 154 in the Z-direction, may be horizontally offset from the first GWL contact structures 154 in the X-direction, and may horizontally overlap the first GWL contact structures 154 in the Y-direction. The GWL routing structures 158 may be vertically interposed between the first GWL contact structures 154 and the second GWL contact structures 156 in the Z-direction, and may horizontally extend (e.g., in the X-direction) between and couple individual first GWL contact structures 154 to individual second GWL contact structures 156.

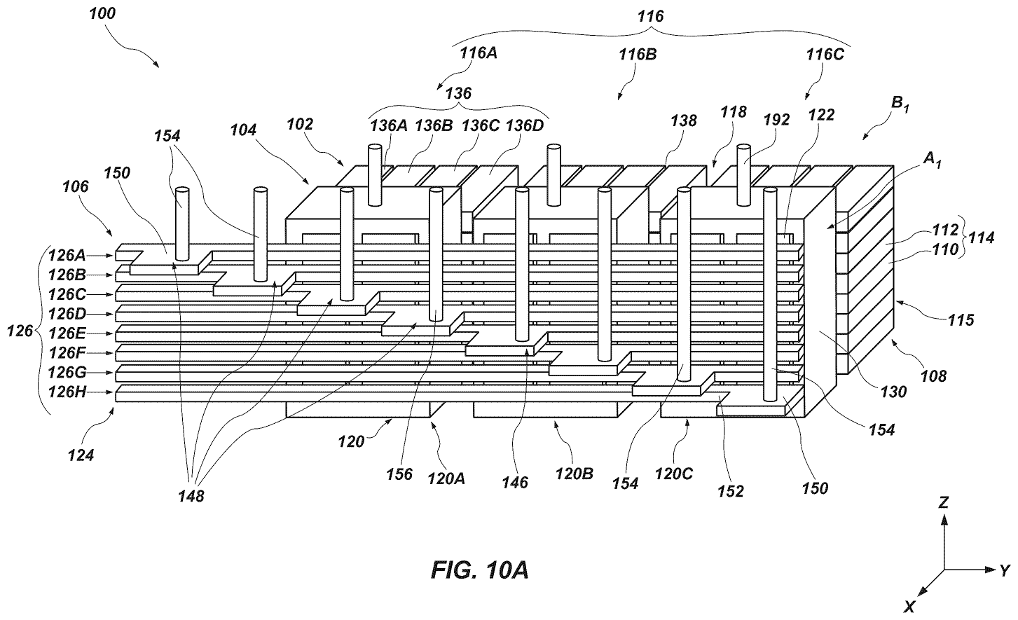

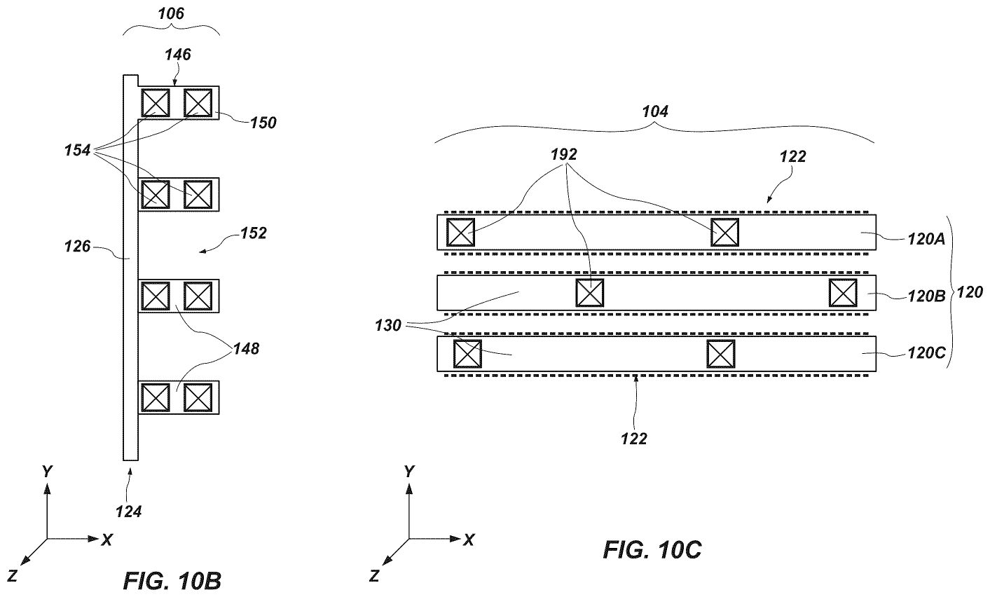

In some embodiments, at least some of the contact structures (e.g., the first GWL contact structures 154, the first BS contact structures 192) within an individual in-tier GWL region 106 and/or an individual in-tier BS region 104 of the microelectronic device 100 are configured to facilitate bonding (e.g., metal-to-metal bonding) between the contact structures and conductive features (e.g., additional contact structures, routing structures, bond pad structures) of a separately formed microelectronic device structure (e.g., a control circuitry structure including control logic circuitry). For example, in accordance with some embodiments of the disclosure, FIG. 10A is a simplified, partial-cutaway perspective view (FIG. 10A) of the microelectronic device 100 showing contact structure configurations within an individual in-tier GWL region 106 and an individual in-tier BS region 104 that accommodate such bonding. FIG. 10B shows a schematic, top-down view of a portion of the in-tier GWL region 106 shown in FIG. 10A. FIG. 10C shows a schematic, top-down view of a portion of the in-tier BS region 104 shown in FIG. 10A.

Referring to FIG. 10A, within the in-tier GWL region 106, the microelectronic device 100 may include the first GWL contact structures 154 on the steps 148 of the GWL staircase structure 146. However, the in-tier GWL region 106 may be free of the second GWL contact structures 156 and the GWL routing structures 158 previously described herein with reference to FIGS. 6A, 6B, 9A, and 9B. The first GWL contact structures 154 may be serve, in-part, as bond pad structures for the aforementioned bonding (e.g., metal-to-metal bonding) with conductive features (e.g., additional contact structures, routing structures, pad structures) of a separately formed microelectronic device structure (e.g., control circuitry structure including control logic circuitry). In addition, within the in-tier BS region 104, the microelectronic device 100 may include the first BS contact structures 192 on the gate electrode material 130 of the BS devices 120. However, the in-tier BS region 104 may be free of the second BS contact structures 190 and the BS routing structures 194 previously described herein with reference to FIG. 9B. The first BS contact structures 192 may be serve, in-part, as other bond pad structures for the aforementioned bonding (e.g., metal-to-metal bonding) with other conductive features of the separately formed microelectronic device structure.

Referring next to FIG. 10B, within the in-tier GWL region 106, the first GWL contact structures 154 may be provided at desired horizontal positions (i.e., in the X-direction, in the Y-direction) on the steps 148 of the GWL staircase structure 146. A horizontal centerline, in the Y-direction, of an individual first GWL contact structure 154 may be substantially aligned with a horizontal centerline, in the Y-direction, of an individual step 148 in contact therewith; or a horizontal centerline, in the Y-direction, of an individual first GWL contact structure 154 may be offset from a horizontal centerline, in the Y-direction, of an individual step 148 in contact therewith. In addition, a horizontal centerline, in the X-direction, of an individual first GWL contact structure 154 may be substantially aligned with a horizontal centerline, in the X-direction, of an individual step 148 in contact therewith; or a horizontal centerline, in the X-direction, of an individual first GWL contact structure 154 may be offset from a horizontal centerline, in the X-direction, of an individual step 148 in contact therewith. In addition, first GWL contact structures 154 on different steps 148 than one another may at least partially (e.g., substantially) horizontally overlap one another in the X-direction, or may be horizontally offset from one another in the X-direction.

As shown in FIG. 10B, in some embodiments, multiple (e.g., more than one) first GWL contact structures 154 are located on an individual step 148 of the GWL staircase structure 146. For example, an individual step 148 of the GWL staircase structure 146 may include two (2) of the first GWL contact structures 154 thereon. The two (2) of the first GWL contact structures 154 may at least partially (e.g., substantially) horizontally overlap one another in the Y-direction and may be horizontally offset from one another in the X-direction. In addition, pairs (e.g., groups of two (2)) of the first GWL contact structures 154 on different steps 148 than one another may at least partially (e.g., substantially) horizontally overlap one another in the X-direction, or may be horizontally offset from one another in the X-direction. In additional embodiments, a single (e.g., only one) first GWL contact structure 154 is located on an individual step 148 of the GWL staircase structure 146. Each step 148 of the GWL staircase structure 146 may include multiple (e.g., two (2)) first GWL contact structures 154 thereon; each step 148 of the GWL staircase structure 146 may include only one first GWL contact structure 154 thereon; or some of the steps 148 of the GWL staircase structure 146 may respectively include multiple (e.g., two (2)) first GWL contact structures 154 thereon, and some others of the steps 148 of the GWL staircase structure 146 may respectively include only one (1) first GWL contact structure 154 thereon.

The relative arrangements and quantities of the first GWL contact structures 154 described herein with reference to FIG. 10B are also applicable to the configurations C₁, C₂, C₃, E₁, and E₂ previously described herein with reference to FIGS. 6A, 6B, 6C, 9A, and 9B, respectively, and without limitation.

Referring next to FIG. 10C, within the in-tier BS region 104, the first BS contact structures 192 may be provided at desired horizontal positions (i.e., in the X-direction, in the Y-direction) on the gate electrode material 130 of the BS devices 120. A horizontal centerline, in the Y-direction, of an individual first BS contact structure 192 may be substantially aligned with a horizontal centerline, in the Y-direction, of an individual BS device 120 in contact therewith; or a horizontal centerline, in the Y-direction, of an individual first BS contact structure 192 may be offset from a horizontal centerline, in the Y-direction, of an individual BS device 120 in contact therewith. In addition, a horizontal centerline, in the X-direction, of an individual first BS contact structure 192 may be substantially aligned with a horizontal centerline, in the X-direction, of an individual BS device 120 in contact therewith; or a horizontal centerline, in the X-direction, of an individual first BS contact structure 192 may be offset from a horizontal centerline, in the X-direction, of an individual BS device 120 in contact therewith. First BS contact structures 192 on different BS devices 120 than one another may at least partially (e.g., substantially) horizontally overlap one another in the X-direction or may be horizontally offset from one another in the X-direction. In some embodiments, for BS devices 120 horizontally neighboring one another in the Y-direction (e.g., the first BS device 120A and the second BS device 120B, the second BS device 120B and the third BS device 120C), the first BS contact structures 192 of one (1) of the BS devices 120 (e.g., the first BS device 120A) are horizontally offset, in the X-direction, from the first BS contact structures 192 most horizontally proximate (e.g., in the X-direction and the Y-direction) thereto on the other one (1) of the BS devices 120 (e.g., the second BS device 120B).

As shown in FIG. 10C, in some embodiments, multiple (e.g., more than one) first BS contact structures 192 are located on an individual BS device 120. For example, an individual BS device 120 may include two (2) of the BS contact structures 192. The two (2) of the first BS contact structures 192 may at least partially (e.g., substantially) horizontally overlap one another in the Y-direction, and may be horizontally offset from one another in the X-direction. In addition, pairs (e.g., groups of two (2)) of the first BS contact structures 192 on different BS devices 120 than one another may at least partially (e.g., substantially) horizontally overlap one another in the X-direction or may be horizontally offset from one another in the X-direction. In some embodiments, pairs of the first BS contact structures 192 on one of the BS devices 120 (e.g., the first BS device 120A) are horizontally staggered (e.g., horizontally offset), in the X-direction, relative to pairs of the first BS contact structures 192 on another one of the BS devices 120 (e.g., the second BS device 120B) horizontally neighboring the one of the BS devices 120 in the Y-direction. In additional embodiments, a single (e.g., only one) first BS contact structure 192 is located on an individual BS device 120. Each BS device 120 may include multiple (e.g., two (2)) first BS contact structures 192 thereon; each BS device 120 may include only one (1) first BS contact structure 192 thereon; or some of the BS devices 120 may respectively include multiple (e.g., two (2)) first BS contact structures 192 thereon, and some others of the BS devices 120 may respectively include only one (1) first BS contact structure 192 thereon.

The relative arrangements and quantities of the first BS contact structures 192 described herein with reference to FIG. 10B are also applicable to the configuration E₂ previously described herein with reference to FIG. 9B, without limitation.

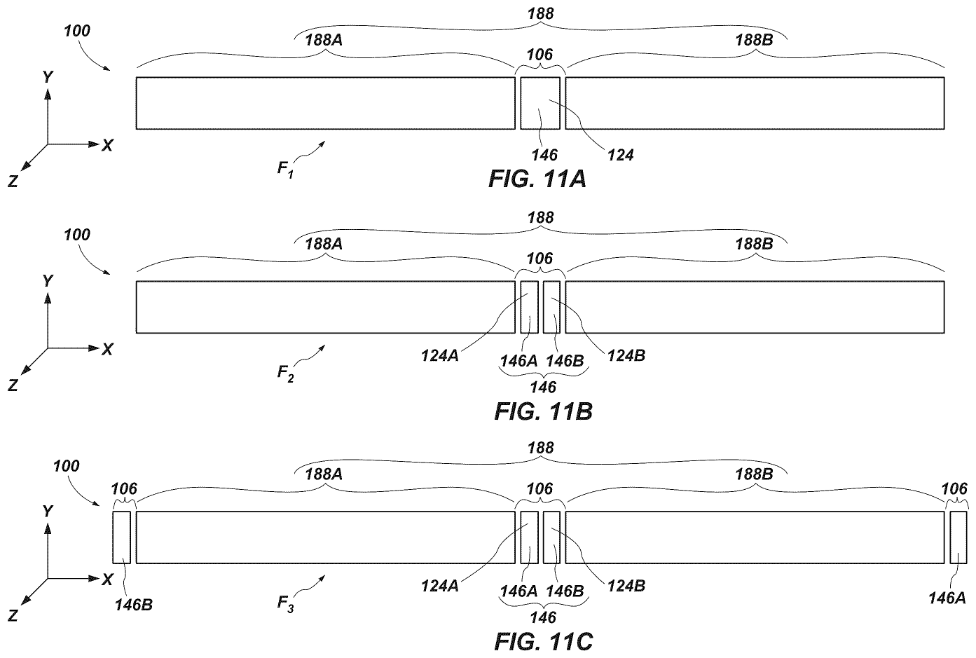

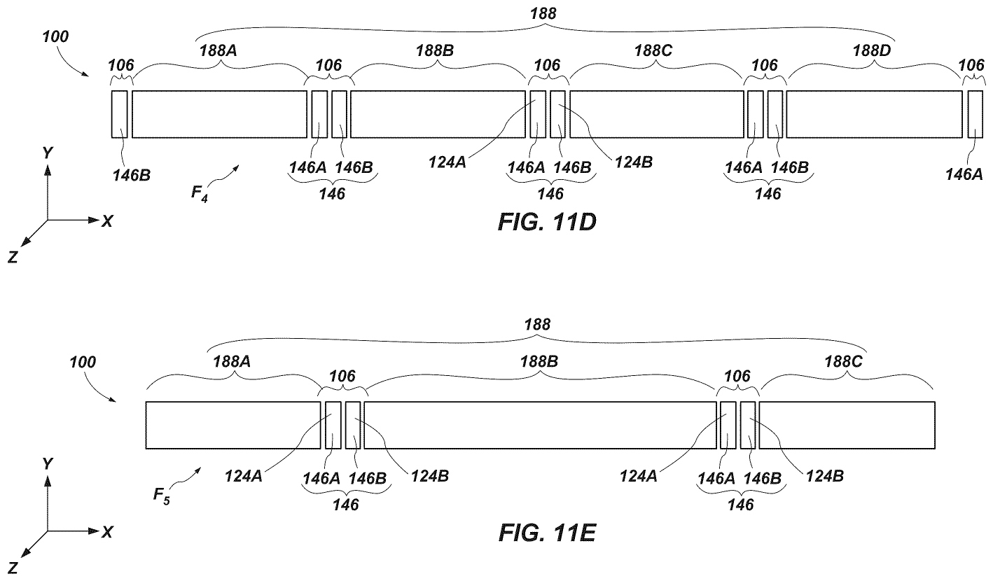

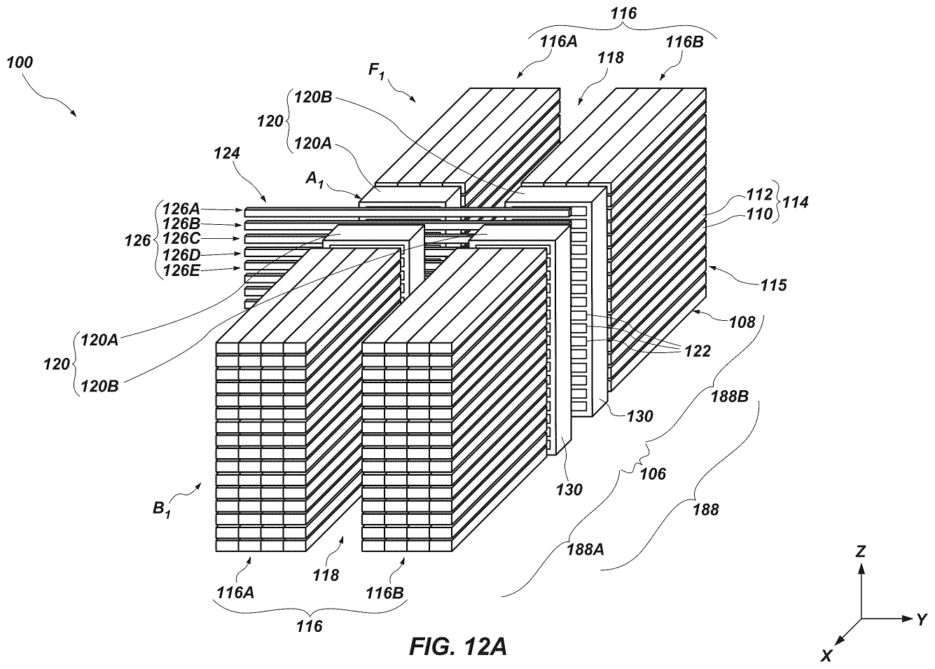

Referring briefly again to FIG. 9A, as previously described herein, the microelectronic device 100 may be configured to include multiple (e.g., more than one) block sections 188 and at least one in-tier GWL region 106 operatively associated with the multiple block sections 188. In this regard, in accordance with embodiments of the disclosure, FIGS. 11A through 11E are simplified plan views of different configurations F₁ (FIG. 11A), F₂ (FIG. 11B), F₃ (FIG. 11C), F₄ (FIG. 11D), and F₅(FIG. 11E) that may be employed for the microelectronic device 100, wherein the different configurations F₁ through F₅ include different arrangements of block sections 188 and one or more in-tier GWL regions 106 than one another. It will be understood that any of the configurations F₁ through F₅ shown in FIGS. 11A through 11E and described in further detail below may be employed for the microelectronic device 100.

Referring first to FIG. 11A, a configuration F₁ for the microelectronic device 100 may include two (2) block sections 188, and a single (e.g., only one) in-tier GWL region 106 horizontally interposed between the two (2) block sections 188 in the X-direction. The two (2) block sections 188 may include a first block section 188A and a second block section 188B. In some embodiments, the first block section 188A includes a first half-plane of blocks 116 (see e.g., FIG. 6A) and associated BS devices 120 (see e.g., FIG. 6A); and the second block section 188B includes a second half-plane of blocks 116 (see e.g., FIG. 6A) and associated BS devices 120 (see e.g., FIG. 6A). The in-tier GWL region 106 may be centrally positioned, in the X-direction, between the first block section 188A and the second block section 188B. The in-tier GWL region 106 may include a single (e.g., only one) GWL staircase structure 146 (or two (2) GWL staircase structures 146 coupled to one another to effectively act as a single GWL staircase structure 146) shared by at least one GWL stack 124 operatively associated with each of the first block section 188A and the second block section 188B. The configuration F₁ of FIG. 11A may be considered “single-ended” for the first block section 188A and the second block section 188B since there is only one in-tier GWL region 106, positioned at a single end (in the X-direction) of the first block section 188A and a single end (in the X-direction) of the second block section 188B.

Referring next to FIG. 11B, a configuration F₂ for the microelectronic device 100 may be similar to the configuration F₁ of FIG. 11A, including two (2) block sections 188 (e.g., a first block section 188A, a second block section 188B), and a single (e.g., only one) in-tier GWL region 106 horizontally interposed between the two (2) block sections 188 in the X-direction. However, unlike the configuration F₁ of FIG. 11A, the in-tier GWL region 106 may include two (2) GWL staircase structures 146 that are separate and discrete from one another (e.g., are not coupled to one another). A first GWL staircase structure 146A may be operatively associated with a first GWL stack 124A operatively associated with the first block section 188A. A second GWL staircase structure 146B may be separate and discrete from the first GWL staircase structure 146A and may be operatively associated with a second GWL stack 124B operatively associated with the second block section 188B. The configuration F₂ of FIG. 11B may also be considered “single-ended” for the first block section 188A and the second block section 188B since there is only one in-tier GWL region 106, positioned at a single end (in the X-direction) of the first block section 188A and a single end (in the X-direction) of the second block section 188B.

Referring next to FIG. 11C, a configuration F₃ for the microelectronic device 100 may be similar to the configuration F₂ of FIG. 11B, including two (2) block sections 188 (e.g., a first block section 188A, a second block section 188B); and one in-tier GWL region 106 horizontally interposed between the two (2) block sections 188 in the X-direction and including two (2) GWL staircase structures 146 therein. However, the configuration F₃ of FIG. 11C also includes two (2) more in-tier GWL regions 106, for a total of three (3) in-tier GWL regions 106. Two (2) of the in-tier GWL regions 106 (e.g., a middle one of the in-tier GWL regions 106, and an additional one of the in-tier GWL regions 106) may be operatively associated with and at opposing ends, in the X-direction, of the first block section 188A. The first block section 188A may be horizontally interposed between the two (2) of the in-tier GWL regions 106, including two (2) GWL staircase structures 146 (and two (2) associated GWL stacks 124) thereof. The two (2) GWL staircase structures 146 of the two (2) in-tier GWL regions 106 may individually be operatively associated with blocks 116 (FIG. 1) and BS devices 120 (FIG. 1) of the first block section 188A. In addition, another two (2) of the in-tier GWL regions 106 (e.g., the middle one of the in-tier GWL regions 106, and another one of the in-tier GWL regions 106) may be operatively associated with and at opposing ends, in the X-direction, of the second block section 188B. The second block section 188B may be horizontally interposed between the another two (2) of the in-tier GWL regions 106, including another two (2) GWL staircase structures 146 (and another two (2) associated GWL stacks 124) thereof. The another two (2) GWL staircase structures 146 of the another two (2) in-tier GWL regions 106 may individually be operatively associated with blocks 116 (see e.g., FIG. 6A) and BS devices 120 (see e.g., FIG. 6A) of the second block section 188B. The configuration F₃ of FIG. 11C may be considered “double-ended” for the first block section 188A and the second block section 188B since each of the first block section 188A and the second block section 188B has two (2) in-tier GWL regions 106 positioned at opposing ends (in the X-direction) thereof.

Referring next to FIG. 11D, a configuration F₄ for the microelectronic device 100 may be similar to the configuration F₃ of FIG. 11C but may include four (4) block sections 188 and five (5) in-tier GWL regions 106 collectively operatively associated with the four (4) block sections 188. The four (4) block sections 188 may include a first block section 188A, a second block section 188B, a third block section 188C, and a fourth block section 188D. In some embodiments, the first block section 188A includes a first quarter-plane of blocks 116 (see e.g., FIG. 6A) and associated BS devices 120 (see e.g., FIG. 6A); the second block section 188B includes a second quarter-plane of blocks 116 (see e.g., FIG. 6A) and associated BS devices 120 (see e.g., FIG. 6A); the third block section 188C includes a third quarter-plane of blocks 116 (see e.g., FIG. 6A) and associated BS devices 120 (see e.g., FIG. 6A); and the fourth block section 188D includes a fourth quarter-plane of blocks 116 (see e.g., FIG. 6A) and associated BS devices 120 (see e.g., FIG. 6A). The each one of four (4) block sections 188 may respectively be horizontally interposed between the two (2) of the in-tier GWL regions 106, including two (2) GWL staircase structures 146 (and two (2) associated GWL stacks 124) thereof, in a manner similar to that previously described herein in relation to the configuration F₃ of FIG. 11C. The configuration F₄ of FIG. 11D may be considered “double-ended” for the first block section 188A, the second block section 188B, the third block section 188C, and the fourth block section 188D, since each of the first block section 188A, the second block section 188B, the third block section 188C, and the fourth block section 188D has two (2) in-tier GWL regions 106 positioned at opposing ends (in the X-direction) thereof.

Referring next to FIG. 11E, a configuration F₅ for the microelectronic device 100 may have similarities to the configuration F₂ of FIG. 11B and the configuration F₄ of FIG. 11D but may include three (3) block sections 188 and two (2) in-tier GWL regions 106 collectively operatively associated with the three (3) block sections 188. The three (3) block sections 188 may include a first block section 188A, a second block section 188B, and a third block section 188C. In some embodiments, the first block section 188A includes a first quarter-plane of blocks 116 (see e.g., FIG. 6A) and associated BS devices 120 (see e.g., FIG. 6A); the second block section 188B includes a first half-plane of blocks 116 (see e.g., FIG. 6A) and associated BS devices 120 (see e.g., FIG. 6A); and the third block section 188C includes a second quarter-plane of blocks 116 (see e.g., FIG. 6A) and associated BS devices 120 (see e.g., FIG. 6A). Each of the two (2) in-tier GWL regions 106 may include two (2) GWL staircase structures 146. One of the two (2) in-tier GWL regions 106 may be horizontally interposed in the X-direction between and operatively associated with each of the first block section 188A and the second block section 188B; one other of the two (2) in-tier GWL regions 106 may be horizontally interposed in the X-direction between and operatively associated with each of the second block section 188B and the third block section 188C. The configuration F₅ of FIG. 11E may be considered “single-ended” for the first block section 188A and the third block section 188C, since each of the first block section 188A and the third block section 188C has only one in-tier GWL region 106 positioned at a single end (in the X-direction) thereof; and may be considered “double-ended” for the second block section 188B, since the second block section 188B has two (2) in-tier GWL regions 106 positioned at opposing ends (in the X-direction) thereof.

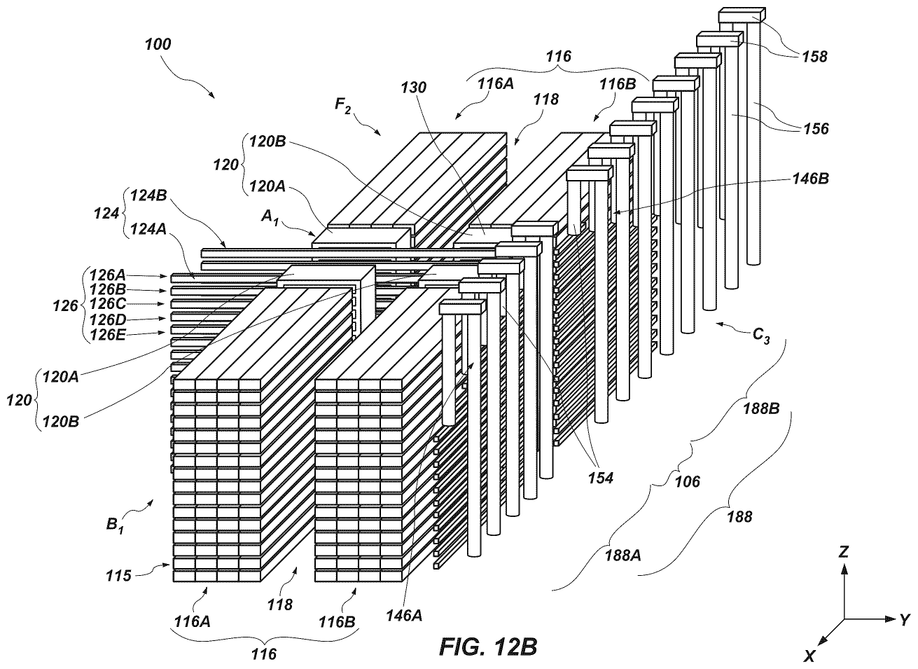

Referring collectively to FIGS. 12A and 12B, depicted are simplified, partial-cutaway perspective views of different configurations that may be employed for the microelectronic device 100 to facilitate different block select operations (e.g., drive different BS devices 120) for different block sections 188 thereof. The overall configurations depicted in FIGS. 12A and 12B respectively employ various feature configurations previously described herein with reference to one or more of FIGS. 1 through 11E. For example, the overall configuration shown in FIG. 12A employs a combination of the configurations A₁ (FIG. 2A), B₁ (FIGS. 3A and 3B), C₁ (FIG. 6A), and F₁ (FIG. 11A) previously described herein, without limitation. As another example, the overall configuration shown in FIG. 12B employs a combination of the configurations A₁ (FIG. 2A), B₁ (FIGS. 3A and 3B), C₃ (FIG. 6C), and F₂ (FIG. 11B) previously described herein, without limitation. While the overall configurations of FIGS. 12A and 12B depict combinations of feature configurations previously described herein, it will be understood that the disclosure is not so limited, and that other feature configurations previously described herein with reference to one or more of FIGS. 1 through 11E may be employed in place of and/or in addition to at least some of the feature configurations depicted in FIGS. 12A and 12B.

Referring to FIG. 12A, for the depicted configuration of the microelectronic device 100, the GWL stack 124 within the in-tier GWL region 106 is shared by (e.g., common to) the first block section 188A and the second block section 188B. Accordingly, selective activation of BS devices 120 of the first block section 188A and the second block section 188B may be employed to direct a signal (e.g., a GWL signal) from a GWL structure 126 of the GWL stack 124 to a LWL structure 115 of an individual block 116 within one of the first block section 188A and the second block section 188B without directing the signal to a different, individual block 116 within the other of the first block section 188A and the second block section 188B. As a non-limiting example, a first BS device 120A within the first block section 188A may be activated (e.g., by way of a BS signal directed to the gate electrode material 130 thereof), while each of a second BS device 120B within the first block section 188A, a first BS device 120A within the first block section 188A, and a second BS device 120B within the first block section 188A are not activated (e.g., individually and collectively remain inactive). As a result of such selective activation, a signal directed from an individual GWL structure 126 of the GWL stack 124 may be directed to an individual LWL structure 115 of the first block 116A of the first block section 188A operatively associated with the activated first BS device 120A, without directing the signal to LWL structures 115 of a second block 116B of the first block section 188A, a first block 116A of the second block section 188B, and a second block 116B of the second block section 188B.

Referring next to FIG. 12B, for the depicted configuration of the microelectronic device 100, two (2) GWL stacks 124 may be positioned in-tier GWL region 106 and may be separate and discrete from another (e.g., not coupled to one another). A first GWL stack 124A may be operatively associated with the first block section 188A and a first GWL staircase structure 146A. The second GWL stack 124B may be operatively associated with the second block section 188B and a second GWL staircase structure 146B. The first GWL staircase structure 146A and the second GWL staircase structure 146B may respectively be located outside of the in-tier GWL region 106 (e.g., the configuration C₃, as shown in FIG. 12B), or may respectively be located within the in-tier GWL region 106 (e.g., one of the configurations C₁ and C₂ previously described herein with reference to FIGS. 6A and 6B). As a result of the configuration depicted in FIG. 12B, the first block section 188A and the second block section 188B may be controlled independently from one another. Since the first GWL stack 124A and the second GWL stack 124B are separate and discrete from one another, a signal (e.g., a GWL signal) may be directed to the BS devices 120 of the first block section 188A by way of first GWL stack 124A without directing the signal to the BS devices 120 of the first block section 188A, or a signal (e.g., a GWL signal) may be directed to the BS devices 120 of the second block section 188B by way of second GWL stack 124B without directing the signal to the BS devices 120 of the first block section 188A. In addition, the BS devices 120 of the first block section 188A may be selectively activated (e.g., by way of a BS signal directed to the gate electrode material 130 thereof) relative to one another and the BS devices 120 of the first block section 188A, and the BS devices 120 of the second block section 188B may be selectively activated (e.g., by way of a BS signal directed to the gate electrode material 130 thereof) relative to one another and the BS devices 120 of the first block section 188A. Accordingly, an individual block 116 of one of the first block section 188A and the second block section 188B may be accessed and controlled independent from all others of the blocks 116 of the first block section 188A and the second block section 188B. Furthermore, any individual block 116 of one of the first block section 188A and the second block section 188B may be accessed and controlled while also separately and simultaneously accessing and controlling any other individual block 116 of the other one of the first block section 188A and the second block section 188B.

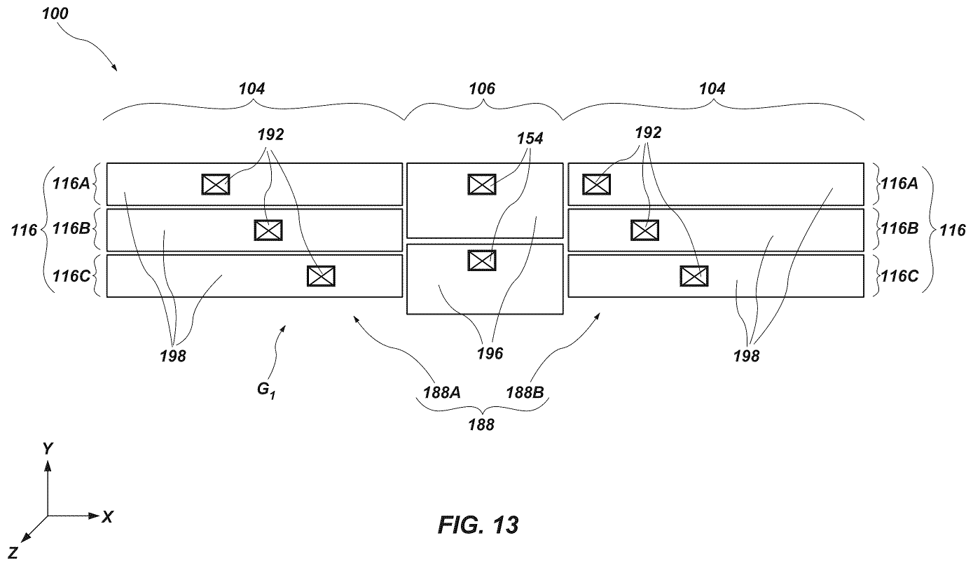

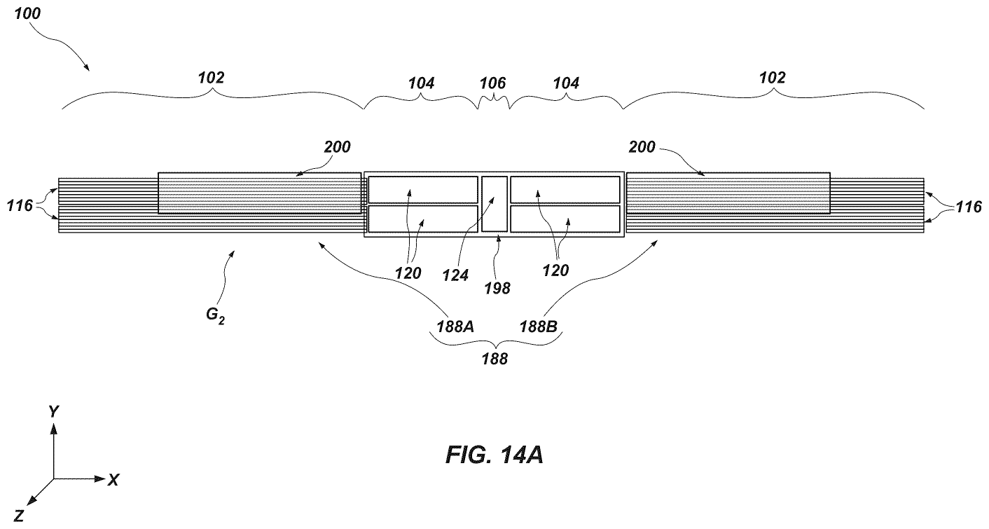

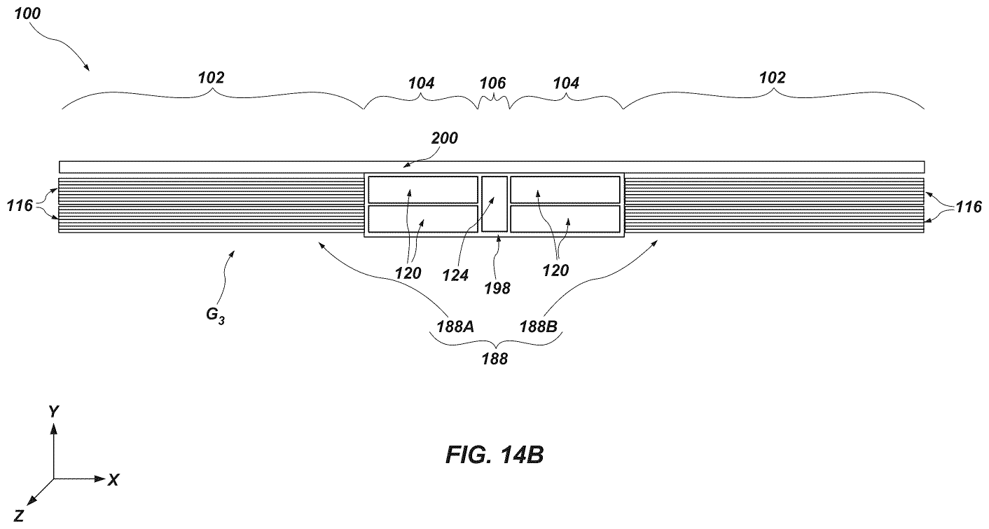

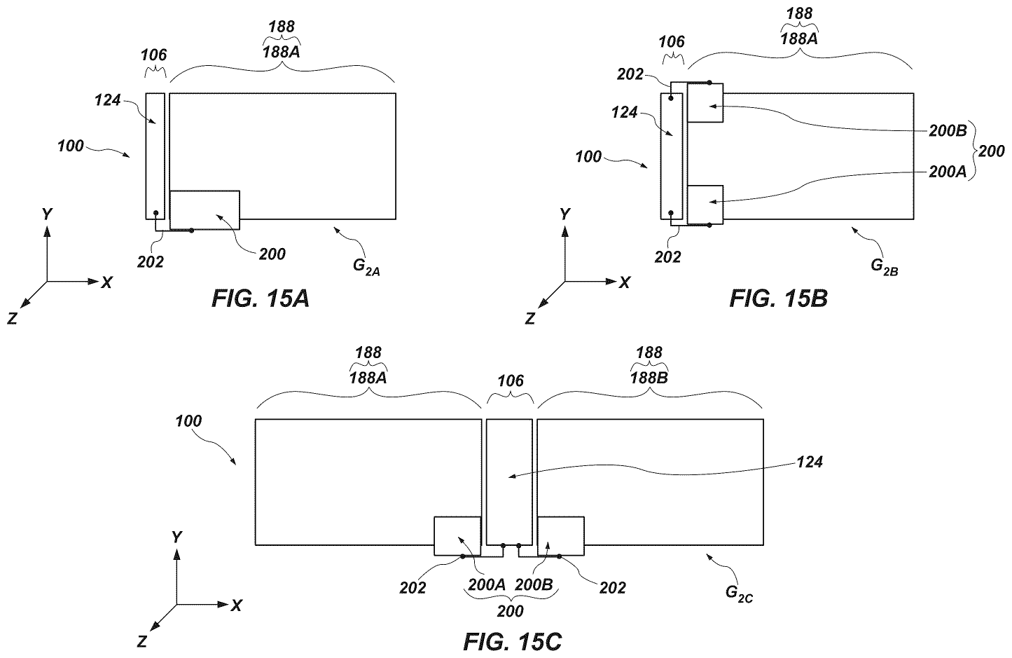

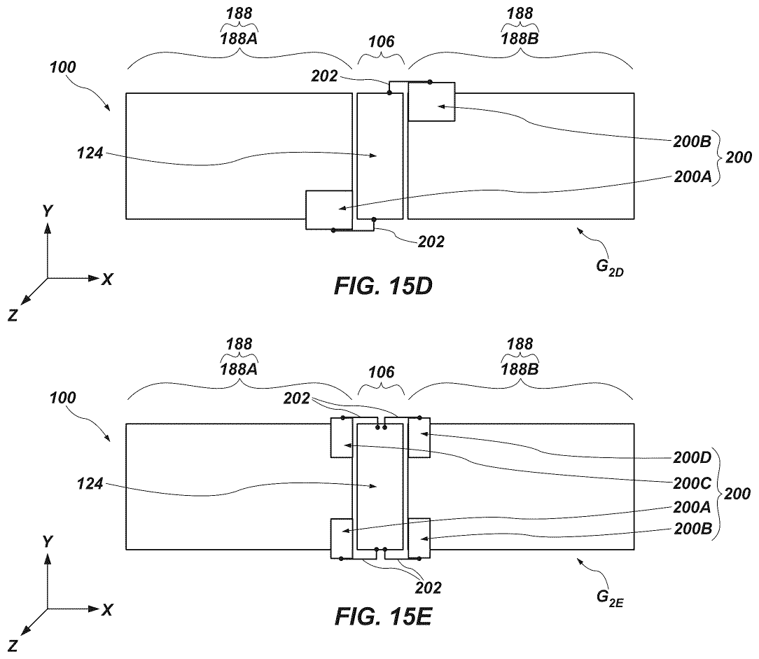

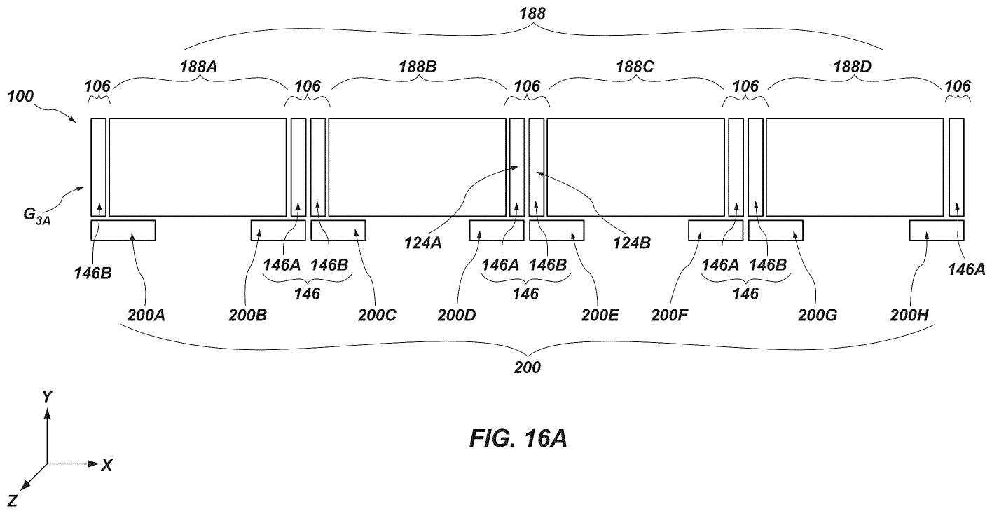

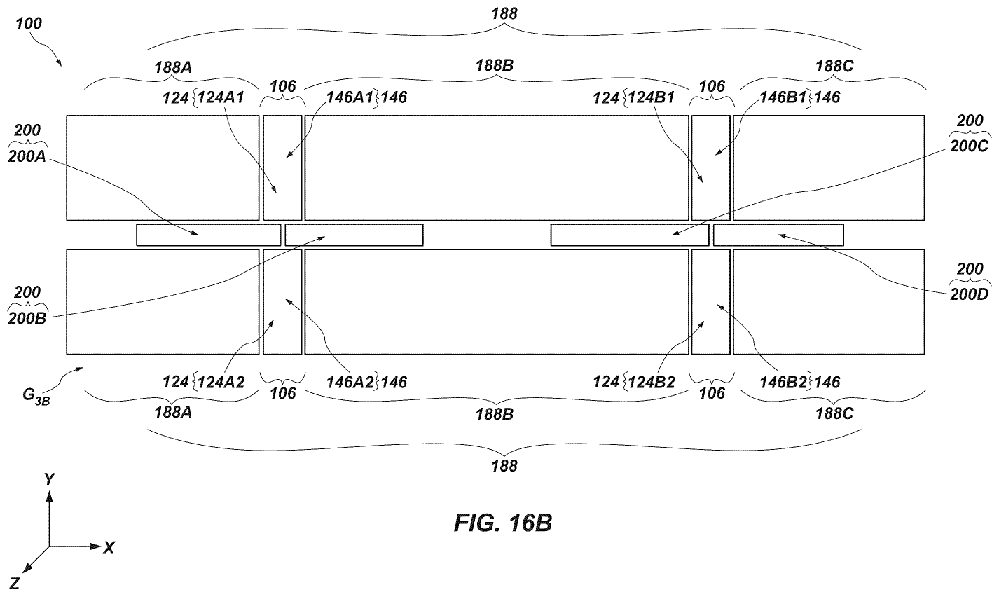

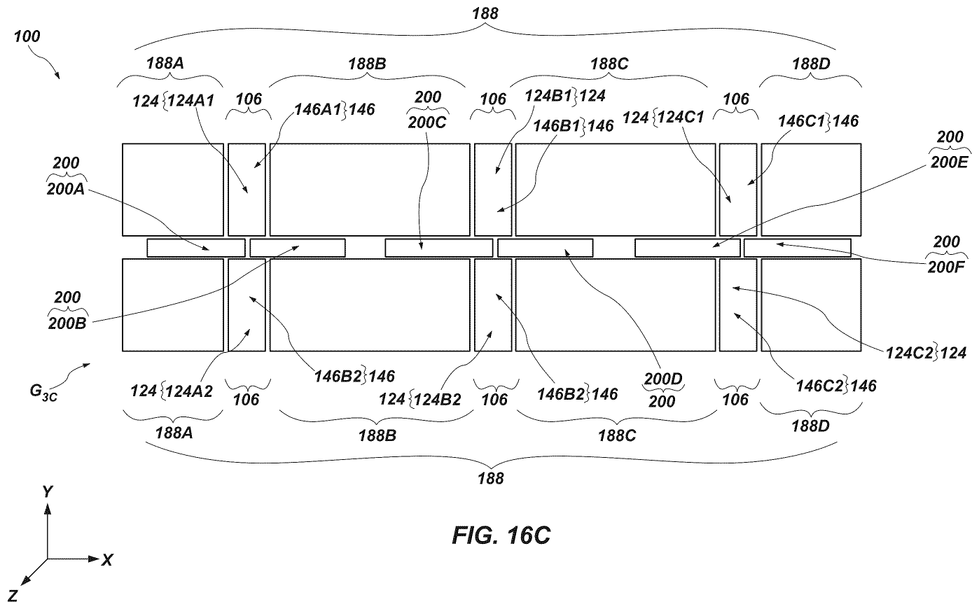

With collective reference to FIGS. 1 through 12B, various configurations previously described herein for the microelectronic device 100, including (without limitation) the vertical positions (e.g., “in-tier” positions) and configurations of the BS devices 120 and the GWL stack(s) 124 thereof, facilitate a variety of control logic circuitry (e.g., GWL driver circuitry, GWL generator circuitry, BS generator circuitry) configurations for the microelectronic device 100. As previously discussed herein (e.g., in relation to the BS generator devices 140 (FIG. 3B)), at least some of the control logic circuitry may be vertically offset from the blocks 116 of the stack structure 108 (and, hence, the BS devices 120 and the GWL stacks 124), as previously discussed herein with reference to FIG. 3B (e.g., the BS generator devices 140). In this regard, FIGS. 13 through 16C are simplified plan views of different control logic circuitry configurations that may be employed within the microelectronic device 100. FIGS. 13, 14, and 14B show different control logic circuitry configurations G₁ (FIG. 13), G₂ (FIG. 14A), and G₃ (FIG. 14C). FIGS. 15A through 15E show different control logic circuitry configurations G_{2A} (FIG. 15A), G_{2B} (FIG. 15B), G_{2C} (FIG. 15C), G_{2D} (FIG. 15D), and G_{2E} (FIG. 15E), each of which may be within the general scope and breadth of the control logic circuitry configuration G₂ (FIG. 14A). FIGS. 16A through 16C show different control logic circuitry configurations G_{3A}(FIG. 16A), G_{3B} (FIG. 16B), and G_{3C} (FIG. 16C), each of which may be within the general scope and breadth of the control logic circuitry configuration G₃ (FIG. 14B).

Referring to FIG. 13, the control logic circuitry configuration G₁ for the microelectronic device 100 may include, without limitation, GWL driver regions 196 and BS generator regions 198. The GWL driver regions 196 may respectively be within a horizontal area of an individual in-tier GWL region 106 of the microelectronic device 100. The BS generator regions 198 may respectively be within a horizontal area of an individual block section 188 of the microelectronic device 100. The GWL driver regions 196 may include GWL driver devices operatively associated with GWL structures 126 (see e.g., FIG. 6A) of GWL stack(s) 124 (see e.g., FIG. 6A) within the in-tier GWL region 106 at least by way of the first GWL contact structures 154. The BS generator regions 198 may include BS generator devices (e.g., the BS generator devices 140 (FIG. 3B)) operatively associated with BS devices 120 (see e.g., FIG. 6A) within the in-tier BS regions 104 at least by way of the first BS contact structures 192.

As shown in FIG. 13, the GWL driver regions 196 may respectively be substantially confined within the horizontal area of an individual in-tier GWL region 106 of the microelectronic device 100. The GWL driver regions 196 may individually and collectively be horizontally interposed, in the X-direction, between two (2) groups of the BS generator regions 198 located within horizontal areas of different block sections 188 (e.g., the first block section 188A and the second block section 188B) than one another. The GWL driver regions 196 may horizontally overlap (e.g., may be substantially horizontally aligned with) one another in the X-direction, and may be horizontally offset from one another in the Y-direction. Each of the GWL driver regions 196 may have substantially a same size and a same shape as each other of the GWL driver regions 196, or at least one of the GWL driver regions 196 may have a different size and/or a different shape than at least one other of the GWL driver regions 196.

The BS generator regions 198 may respectively be substantially confined within a horizontal area of an individual block section 188 (e.g., the first block section 188A, the second block section 188B) of the microelectronic device 100. As shown in FIG. 13, in some embodiments, the BS generator regions 198 are respectively substantially confined within the horizontal area of an individual in-tier BS region 104 (e.g., an in-tier BS region 104 of the first block section 188A, an in-tier BS region 104 of the second block section 188B) of the microelectronic device 100. An individual BS generator region 198 may be confined within the horizontal span, in the Y-direction, of an individual block 116 within an individual block section 188 of the microelectronic device 100. For a group of the BS generator regions 198 within a horizontal area of an individual block section 188, the BS generator regions 198 of the group may horizontally overlap (e.g., may be substantially horizontally aligned with) one another in the X-direction, and may be horizontally offset from one another in the Y-direction. Each of the BS generator regions 198 may have substantially a same size and a same shape as each other of the BS generator regions 198, or at least one of the BS generator regions 198 may have a different size and/or a different shape than at least one other of the BS generator regions 198.

Referring next to FIG. 14A, the control logic circuitry configuration G₂ for the microelectronic device 100 may include a BS generator region 198 and GWL generator regions 200. The BS generator region 198 may be within a horizontal area of a combination of an individual in-tier GWL region 106 and in-tier BS regions 104 of block sections 188 horizontally neighboring the in-tier GWL region 106. The GWL generator regions 200 may respectively be within a horizontal area of an individual block array region 102 of an individual block section 188 of the microelectronic device 100. The BS generator regions 198 may include BS generator devices (e.g., the BS generator devices 140 (FIG. 3B)) operatively associated with BS devices 120 (see e.g., FIG. 6A) within the in-tier BS regions 104. The GWL generator regions 200 may include GWL generator devices operatively associated with GWL structures 126 (see e.g., FIG. 6A) of GWL stack(s) 124 (see e.g., FIG. 6A) within the in-tier GWL region 106.

As shown in FIG. 14A, an individual BS generator region 198 may horizontally extend, in the X-direction, across an individual in-tier GWL region 106 and two (2) in-tier BS regions 104 of two (2) different block sections 188 (e.g., the first block section 188A and the second block section 188B) horizontally neighboring the in-tier GWL region 106 in the X-direction. The BS generator region 198 may be horizontally interposed, in the X-direction, between two (2) block array regions 102 of two (2) different block sections 188 of the microelectronic device 100. For example, the BS generator region 198 may horizontally extend, in the X-direction, from a group of the blocks 116 within the block array region 102 of the first block section 188A to another group of the blocks 116 within the block array region 102 of the second block section 188B. In addition, the BS generator region 198 may horizontally extend, in the Y-direction, across multiple blocks 116 of the two (2) different block sections 188 (and, hence, multiple BS devices 120 and GWL stack(s) 124 operatively associated with the multiple blocks 116).

The GWL generator regions 200 may respectively be substantially confined within a horizontal area of an individual block array region 102 of an individual block section 188 (e.g., the first block section 188A, the second block section 188B) of the microelectronic device 100. As shown in FIG. 14A, the GWL generator regions 200 may respectively horizontally extend, in the X-direction, from or proximate a boundary (e.g., horizontal end) of the block array region 102 in the in the X-direction partially (e.g., less than completely) across the block array region 102. In addition, the GWL generator regions 200 may respectively horizontally extend, in the Y-direction, across one or more of the blocks 116 of the block array region 102. For example, the GWL generator region 200 horizontally extends, in the Y-direction, from or proximate a boundary (e.g., horizontal end) of the block array region 102 in the Y-direction, and at least partially across one or more (e.g., one, two, three, more than three) of the blocks 116 at or proximate the boundary of the block array region 102. Various potential arrangements for GWL generator region 200 within the control logic circuitry configuration G₂ are described in further detail below with reference to FIGS. 15A through 15E.

Referring next to FIG. 14B, the control logic circuitry configuration G₃ for the microelectronic device 100 may be similar to the control logic circuitry configuration G₂ of FIG. 14A, except that the GWL generator regions 200 thereof do not substantially horizontally overlap, in the Y-direction, any of the blocks 116 of the block sections 188. For example, as shown in FIG. 14B, the GWL generator regions 200 may respectively be positioned outside of a horizontal area of a group of the blocks 116 of an individual block section 188 horizontally neighboring the GWL generator region 200 in the Y-direction. In some embodiments, an individual GWL generator region 200 horizontally extends, in the X-direction, substantially continuously across at least two (2) block sections 188 (e.g., the first block section 188A and the second block section 188B) and at least one in-tier GWL region 106 horizontally interposed between the at least two (2) block sections 188. The GWL generator region 200 may extend, in the X-direction, proximate to and along a common horizontal boundary (e.g., a common horizontal end), in the Y-direction, of the at least two (2) block sections 188 and the at least one in-tier GWL region 106. In additional embodiments, multiple (e.g., more than one) GWL generator regions 200 horizontally overlap one another in the Y-direction, but are horizontally spaced apart from one another in the X-direction. In such embodiments, an individual GWL generator region 200 of the multiple GWL generator regions 200 may horizontally extend, in the X-direction, partially across an individual in-tier GWL region 106 and an individual block section 188 horizontally neighboring the in-tier GWL region 106 in the X-direction. The GWL generator region 200 may extend, in the X-direction, proximate to and along a common horizontal boundary (e.g., a common horizontal end), in the Y-direction, of the in-tier GWL region 106 and the block section 188. Various potential arrangements for GWL generator region 200 within the control logic circuitry configuration G₃ are described in further detail below with reference to FIGS. 16A through 16C.

Now referring collectively to FIGS. 14A and 15A through 15E, as previously mentioned herein, within the control logic circuitry configuration G₂ (FIG. 14A) various different arrangements for the GWL generator regions 200 thereof are feasible. In this regard, FIGS. 15A through 15E depict different control logic circuitry configurations G_{2A} (FIG. 15A), G_{2B} (FIG. 15B), G_{2C} (FIG. 15C), G_{2D} (FIG. 15D), and G_{2E} (FIG. 15E), respectively, within the general scope and breadth of the control logic circuitry configuration G₂ (FIG. 14A) but include different arrangements of GWL generator region(s) 200 relative to one another. It will be understood that any of the control logic circuitry configurations G_{2A}, G_{2B}, G_{2C}, G_{2D}, and G_{2E} shown in FIGS. 15A through 15E and described in further detail below may be employed within the microelectronic device 100.

Referring to FIG. 15A, the control logic circuitry configuration G_{2A} may include an individual GWL generator region 200 horizontally overlapping an individual block section 188 (e.g., the first block section 188A) at or proximate a single (e.g., only one) corner of the block section 188. The corner of the block section 188 may be proximate an in-tier GWL region 106 operatively associated with the block section 188. GWL interconnect structures 202 extending between the GWL generator region 200 and the in-tier GWL region 106 may be employed to couple GWL generator devices within the GWL generator region 200 to an individual GWL stack 124 within the in-tier GWL region 106. While the block array region 102 (FIG. 14A) and the in-tier BS region 104 (FIG. 14A) of the block section 188 are not depicted in FIG. 15A, it will be understood that the GWL generator region 200 is within a horizontal area of the block array region 102 (FIG. 14A) of the block section 188, as previously described herein in relation to the control logic circuitry configuration G₂ of FIG. 14A.

Referring next to FIG. 15B, the control logic circuitry configuration G_{2B} may include two (2) GWL generator regions 200 horizontally overlapping an individual block section 188 (e.g., the first block section 188A) at or proximate two (2) corners of the block section 188. The two (2) GWL generator regions 200 may include a first GWL generator region 200A and a second GWL generator region 200B. The two (2) corners of the block section 188 may respectively be proximate an in-tier GWL region 106 operatively associated with the block section 188. The two (2) GWL generator regions 200 may horizontally overlap one another in the X-direction and may be horizontally offset from one another in the Y-direction. GWL interconnect structures 202 extending between the in-tier GWL region 106 and the two (2) GWL generator regions 200 may be employed to couple GWL generator devices within each of the two (2) GWL generator regions 200 to an individual GWL stack 124 within the in-tier GWL region 106. While the block array region 102 (FIG. 14A) and the in-tier BS region 104 (FIG. 14A) of the block section 188 are not depicted in FIG. 15B, it will be understood that the two (2) GWL generator regions 200 are within a horizontal area of the block array region 102 (FIG. 14A) of the block section 188, as previously described herein in relation to the control logic circuitry configuration G₂ of FIG. 14A.

Referring next to FIG. 15C, the control logic circuitry configuration G_{2C} may include two (2) GWL generator regions 200, wherein the two (2) GWL generator regions 200 are positioned within horizontal areas of different block sections 188 (e.g., the first block section 188A and the second block section 188B) than one another. For example, the two (2) GWL generator regions 200 may include a first GWL generator region 200A within a horizontal area of a first block section 188A, and a second GWL generator region 200B within a horizontal area of a second block section 188B. The first GWL generator region 200A may be at or proximate a corner of the first block section 188A, and the second GWL generator region 200B may be at or proximate a corner of the second block section 188B horizontally opposing the corner of the first block section 188A in the X-direction. The two (2) corners of the two (2) block sections 188 (e.g., first block section 188A and the second block section 188B) associated with the two (2) GWL generator regions 200 may respectively be proximate to an individual in-tier GWL region 106 operatively associated with and horizontally interposed between the two (2) block sections 188. The two (2) GWL generator regions 200 may horizontally overlap one another in the Y-direction and may be horizontally offset from one another in the X-direction. GWL interconnect structures 202 extending between the in-tier GWL region 106 and the two (2) GWL generator regions 200 may be employed to couple GWL generator devices within each of the two (2) GWL generator regions 200 to at least one GWL stack 124 within the in-tier GWL region 106. While the block array region 102 (FIG. 14A) and the in-tier BS region 104 (FIG. 14A) of the block section 188 are not depicted in FIG. 15C, it will be understood that the two (2) GWL generator regions 200 are within horizontal areas of the block array regions 102 (FIG. 14A) of the block sections 188, as previously described herein in relation to the control logic circuitry configuration G₂ of FIG. 14A.

Referring next to FIG. 15D, similar to the control logic circuitry configuration G_{2C} of FIG. 15C, the control logic circuitry configuration G_{2D} may include two (2) GWL generator regions 200 (e.g., a first GWL generator region 200A and a second GWL generator region 200B), wherein the two (2) GWL generator regions 200 are positioned within horizontal areas of different block sections 188 (e.g., the first block section 188A and the second block section 188B) than one another. However, the two (2) GWL generator regions 200 may be at or proximate corners of the two (2) block sections 188 that diagonally (e.g., in the X-direction and the Y-direction) oppose one another. The two (2) corners of the two (2) block sections 188 (e.g., first block section 188A and the second block section 188B) associated with the two (2) GWL generator regions 200 may respectively be proximate to an individual in-tier GWL region 106 operatively associated with and horizontally interposed between the two (2) block sections 188. The two (2) GWL generator regions 200 may be horizontally offset from one another in each of the X-direction and the Y-direction. GWL interconnect structures 202 extending between the in-tier GWL region 106 and the two (2) GWL generator regions 200 may be employed to couple GWL generator devices within each of the two (2) GWL generator regions 200 to at least one GWL stack 124 within the in-tier GWL region 106. While the block array region 102 (FIG. 14A) and the in-tier BS region 104 (FIG. 14A) of the block section 188 are not depicted in FIG. 15D, it will be understood that the two (2) GWL generator regions 200 are within horizontal areas of the block array regions 102 (FIG. 14A) of the block sections 188, as previously described herein in relation to the control logic circuitry configuration G₂ of FIG. 14A.

Referring next to FIG. 15E, the control logic circuitry configuration G_{2E} may include four (4) GWL generator regions 200, wherein two (2) of the four (4) GWL generator regions 200 are positioned within a horizontal area of one of the block sections 188 (e.g., the first block section 188A), and two (2) others of the four (4) GWL generator regions 200 are positioned within a horizontal area of another one of the block sections 188 (e.g., the second block section 188B). For example, the four (4) GWL generator regions 200 may include a first GWL generator region 200A within a horizontal area of a first block section 188A, a second GWL generator region 200B within a horizontal area of a second block section 188B, a third GWL generator region 200C within the horizontal area of the first block section 188A, and a fourth GWL generator region 200D within the horizontal area of the second block section 188B. The first GWL generator region 200A and the third GWL generator region 200C are at or proximate two (2) corners of the first block section 188A; and the second GWL generator region 200B and the fourth GWL generator region 200D are at or proximate two (2) corners of the second block section 188B. The four (4) corners of the first block section 188A and the second block section 188B associated with the four (4) GWL generator regions 200 may respectively be proximate to an individual in-tier GWL region 106 operatively associated with and horizontally interposed between the first block section 188A and the second block section 188B. The first GWL generator region 200A may horizontally overlap the second GWL generator region 200B in the Y-direction and may horizontally overlap the third GWL generator region 200C in the X-direction. The second GWL generator region 200B may horizontally overlap the first GWL generator region 200A in the Y-direction and may horizontally overlap the fourth GWL generator region 200D in the X-direction. The third GWL generator region 200C may horizontally overlap the fourth GWL generator region 200D in the Y-direction, and may horizontally overlap the first GWL generator region 200A in the X-direction. GWL interconnect structures 202 extending between the in-tier GWL region 106 and the four (4) GWL generator regions 200 may be employed to couple GWL generator devices within each of the four (4) GWL generator regions 200 to at least one GWL stack 124 within the in-tier GWL region 106. While the block array region 102 (FIG. 14A) and the in-tier BS region 104 (FIG. 14A) of the block section 188 are not depicted in FIG. 15E, it will be understood that the four (4) GWL generator regions 200 are within horizontal areas of the block array regions 102 (FIG. 14A) of the block sections 188, as previously described herein in relation to the control logic circuitry configuration G₂ of FIG. 14A.

Now referring collectively to FIGS. 14B and 16A through 16C, as previously mentioned herein, within the control logic circuitry configuration G₃ (FIG. 14B) various different arrangements for the GWL generator regions 200 thereof are feasible. In this regard, FIGS. 16A through 16C depict different control logic circuitry configurations G_{3A} (FIG. 16A), G_{3B}(FIG. 16B), and G_{3C} (FIG. 16C), respectively, within the general scope and breadth of the control logic circuitry configuration G₃ (FIG. 14A) but include different arrangements of GWL generator region(s) 200 relative to one another. It will be understood that any of the control logic circuitry configurations G_{3A}, G_{3B}, and G_{3C} shown in FIGS. 16A through 16C and described in further detail below may be employed within the microelectronic device 100.

Referring to FIG. 16A, the control logic circuitry configuration G_{3A} may include multiple GWL generator regions 200 horizontally overlapping one another in the Y-direction, horizontally offset from multiple block sections 188 and multiple in-tier GWL regions 106 in the Y-direction, and respectively horizontally overlapping an individual block section 188 and an individual in-tier GWL region 106 in the X-direction. For example, if the microelectronic device 100 includes four (4) block sections 188 (e.g., a first block section 188A, a second block section 188B, a third block section 188C, and a fourth block section 188D), the microelectronic device 100 may include eight (8) GWL generator regions 200. The eight (8) GWL generator regions 200 may include a first GWL generator region 200A, a second GWL generator region 200B, a third GWL generator region 200C, a fourth GWL generator region 200D, a fifth GWL generator region 200E, a sixth GWL generator region 200F, a seventh GWL generator region 200G, and an eighth GWL generator region 200H. As shown in FIG. 16A, if an individual block section 188 is operatively associated with two (2) GWL staircase structures 146 (e.g., a first GWL staircase structure 146A and a second GWL staircase structure 146B) within two (2) different in-tier GWL regions 106, the two (2) GWL staircase structures 146 may be operatively associated with two (2) different GWL generator regions 200. One of the two (2) different GWL generator regions 200 may horizontally overlap, in the X-direction, the block section 188 and one of the two (2) in-tier GWL regions 106; and another one of the two (2) different GWL generator regions 200 may horizontally overlap, in the X-direction, the block section 188 and another one of the two (2) in-tier GWL regions 106. As a non-limiting example, the first block section 188A may be horizontally interposed between two (2) of the in-tier GWL regions 106; the first GWL generator region 200A may horizontally overlap, in the X-direction, the first block section 188A and one of the two (2) of the in-tier GWL regions 106; and the second GWL generator region 200B may horizontally overlap, in the X-direction, the first block section 188A and another one of the two (2) of the in-tier GWL regions 106. As another non-limiting example, the second block section 188B may be horizontally interposed between two (2) of the in-tier GWL regions 106; the third GWL generator region 200C may horizontally overlap, in the X-direction, the second block section 188B and one of the two (2) of the in-tier GWL regions 106; and the fourth GWL generator region 200D may horizontally overlap, in the X-direction, the second block section 188B and another one of the two (2) of the in-tier GWL regions 106.

Referring nest to FIG. 16B, the control logic circuitry configuration G_{3B} may include multiple GWL generator regions 200 horizontally interposed, in the Y-direction, between two (2) different groups of block sections 188 and two (2) different groups of in-tier GWL regions 106 operatively associated with the two (2) different groups of block sections 188. The multiple GWL generator regions 200 may horizontally overlap one another in the Y-direction; may be horizontally offset from each of the two (2) groups of block sections 188 and each of the two (2) groups of in-tier GWL regions 106 in the Y-direction; and may respectively horizontally overlap, in the X-direction, two (2) different block sections 188 (one block section 188 from each of the two (2) groups of block sections 188) and two (2) different in-tier GWL regions 106 (one in-tier GWL region 106 from each of the two (2) groups of in-tier GWL regions 106). For example, if the two (2) groups of block sections 188 respectively include three (3) block sections 188 (e.g., a first block section 188A, a second block section 188B, and a third block section 188C) and the two (2) groups of in-tier GWL regions 106 respectively include two (2) in-tier GWL regions 106, the microelectronic device 100 may include four (4) GWL generator regions 200. The four (4) GWL generator regions 200 may include a first GWL generator region 200A, a second GWL generator region 200B, a third GWL generator region 200C, and a fourth GWL generator region 200D. The multiple GWL generator regions 200 may be sub-divided into multiple groups of two (2) (e.g., pairs) of the GWL generator regions 200 (e.g., the first GWL generator region 200A and the second GWL generator region 200B; the third GWL generator region 200C and the fourth GWL generator region 200D). Within an individual group of two (2) of the GWL generator regions 200, one (1) of the two (2) of the GWL generator regions 200 may be operatively associated with a GWL staircase structure 146 (and, hence, a GWL stack 124) operatively associate with an individual in-tier GWL region 106 of one (1) of the two (2) groups of in-tier GWL regions 106, and another one (1) of the two (2) of the GWL generator regions 200 may be operatively associated with a GWL staircase structure 146 (and, hence, a GWL stack 124) within an individual in-tier GWL region 106 of another one (1) of the two (2) groups of in-tier GWL regions 106. As a non-limiting example, the first GWL generator region 200A may be operatively associated with a first GWL staircase structure 146A1 (and, hence, a first GWL stack 124A1) operatively associated with one (1) of the in-tier GWL regions 106 horizontally interposed between a first block section 188A and a second block section 188B of one (1) of the two (2) groups of the block sections 188; and the second GWL generator region 200B may be operatively associated with another first GWL staircase structure 146A2 (and, hence, another first GWL stack 124A2) operatively associated with another one (1) of the in-tier GWL regions 106 horizontally interposed between another first block section 188A and another second block section 188B of another one (1) of the two (2) groups of the block sections 188; or vice versa. As an additional non-limiting example, the third GWL generator region 200C may be operatively associated with a second GWL staircase structure 146B1 (and, hence, a second GWL stack 124B1) operatively associated with an additional one (1) of the in-tier GWL regions 106 horizontally interposed between the second block section 188B and a third block section 188C of the one of the two (2) groups of the block sections 188; and the fourth GWL generator region 200D may be operatively associated with another second GWL staircase structure 146B2 (and, hence, another second GWL stack 124B2) operatively associated with a further one (1) of the in-tier GWL regions 106 horizontally interposed between the another second block section 188B and another third block section 188C of the another one (1) of the two (2) groups of the block sections 188; or vice versa.

Referring nest to FIG. 16C, the control logic circuitry configuration G_{3C} may be similar to the control logic circuitry configuration G_{3B} of FIG. 16B but may include a relatively greater quantity of block sections 188 within each of the two (2) different groups of the block sections 188. As a result, the microelectronic device 100 may include a relatively greater quantity of in-tier GWL regions 106 within each of the two (2) different groups of in-tier GWL regions 106, as well as a relatively greater quantity of GWL generator regions 200 horizontally interposed, in the Y-direction, between the two (2) different groups of block sections 188 and the two (2) different groups of in-tier GWL regions 106. For example, the two (2) groups of block sections 188 may respectively include four (4) block sections 188 (e.g., a first block section 188A, a second block section 188B, a third block section 188C, and a fourth block section 188D); the two (2) groups of in-tier GWL regions 106 may respectively include three (3) in-tier GWL regions 106; and the microelectronic device 100 may include six (6) GWL generator regions 200. The six (6) GWL generator regions 200 may include a first GWL generator region 200A, a second GWL generator region 200B, a third GWL generator region 200C, a fourth GWL generator region 200D, a fifth GWL generator region 200E, and a sixth GWL generator region 200F. The first GWL generator region 200A, the second GWL generator region 200B, the third GWL generator region 200C, and the fourth GWL generator region 200D may be operatively associated with the two (2) groups of block sections 188 and the two (2) groups of in-tier GWL regions 106, in a manner substantially similar to that previously described herein for the control logic circuitry configuration G_{3B} of FIG. 16B. In addition, the fifth GWL generator region 200E may be operatively associated with a third GWL staircase structure 146C1 (and, hence, a third GWL stack 124C1) operatively associated with a yet further one (1) of the in-tier GWL regions 106 horizontally interposed between the third block section 188C and a fourth block section 188D of the one (1) of the two (2) groups of the block sections 188; and the sixth GWL generator region 200F may be operatively associated with another third GWL staircase structure 146C2 (and, hence, another third GWL stack 124C2) operatively associated with a yet still further one (1) of the in-tier GWL regions 106 horizontally interposed between the another third block section 188C and another fourth block section 188D of the another one (1) of the two (2) groups of the block sections 188; or vice versa.

Referring collectively to FIGS. 16A through 16C, while the GWL staircase structures 146 are depicted as being within the horizontal areas of the in-tier GWL regions 106, it will be understood that the GWL staircase structures 146 may be horizontally positioned outside of the in-tier GWL regions 106, such as in the manner previously described herein with reference to FIGS. 6C and 12B. Horizontally positioning the GWL staircase structures 146 outside of the in-tier GWL regions 106 may facilitate desirable routing configurations within the microelectronic device 100.

Thus, in accordance with embodiments of the disclosure, a microelectronic device includes a stack structure, block select (BS) devices, and a global word line (GWL) stack. The stack structure has tiers respectively including conductive material. The stack structure is divided into blocks respectively including local word line (LWL) structures vertically stacked relative to one another and individually including a portion of the conductive material of one of the tiers. The BS devices vertically overlap the blocks of the stack structure and respectively include a stack of transistors operatively associated with the LWL structures of one of the blocks. The GWL stack vertically overlaps the BS devices and the blocks of the stack structure and includes GWL structures vertically stacked relative to one another. The GWL stack is operatively associated with multiple of the BS devices.

Furthermore, in accordance with embodiments of the disclosure, a microelectronic device includes a block array region, a global word line (GWL) region, and a block select (BS) region. The block array section includes blocks horizontally extending in parallel in a first direction and separated from one another in a second direction orthogonal to the first direction by insulative slot structures. The blocks respectively include a stack of local word line (LWL) structures. The GWL region includes a stack of GWL structures. The stack of GWL structures horizontally extends in the second direction and vertically overlaps the stack of LWL structures of respective ones of the blocks of the block array section. The BS region is horizontally interposed between the block array section and the GWL region in the first direction. The BS region includes BS devices respectively vertically overlapping and horizontally extending between the stack of GWL structures of the GWL region and the stack of LWL structures of the respective ones of the blocks of the block array section.

Moreover, in accordance with embodiments of the disclosure, a memory device includes blocks, a global word line (GWL) stack, and block select (BS) devices. The blocks respectively include local word line (LWL) structures vertically stacked relative to one another, and strings of memory cells vertically extending through the LWL structures. The GWL stack includes GWL structures at vertical elevations of the LWL structures of respective ones of the blocks. The BS devices are horizontally interposed between the GWL stack and the blocks, and respectively include transistors at the vertical elevations of the LWL structures of the respective ones of the blocks. The transistors individually horizontally extend from one of the GWL structures of the GWL stack to one of the LWL structures of one of the blocks.

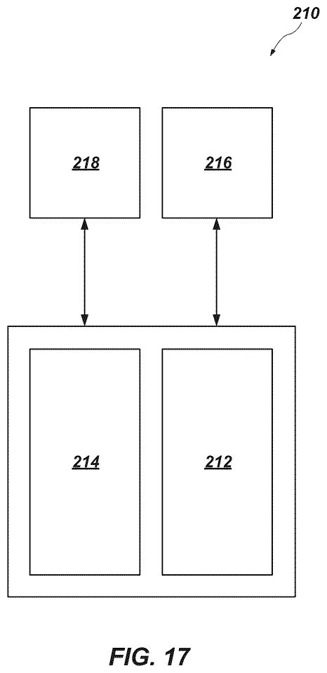

FIG. 17 is a block diagram of an electronic system 210, in accordance with embodiments of the disclosure. The electronic system 210 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 210 includes at least one memory device 212. The memory device 212 may include, for example, an embodiment of a microelectronic device structure and/or a microelectronic device previously described within with respect to one or more of FIGS. 1 through 16C.

The electronic system 210 may further include at least one electronic signal processor device 214 (often referred to as a “microprocessor”). The electronic signal processor device 214 may, optionally, include an embodiment of a microelectronic device structure and/or a microelectronic device previously described within with respect to one or more of FIGS. 1 through 16C. While the memory device 212 and the electronic signal processor device 214 are depicted as two (2) separate devices in FIG. 17, in additional embodiments, a single (e.g., only one) memory/processor device having the functionalities of the memory device 212 and the electronic signal processor device 214 is included in the electronic system 210. In such embodiments, the memory/processor device includes, for example, an embodiment of a microelectronic device structure and/or a microelectronic device previously described within with respect to one or more of FIGS. 1 through 16C.

The electronic system 210 may further include one or more input devices 216 for inputting information into the electronic system 210 by a user, such as, for example, a mouse or other pointing device, a keyboard, a touchpad, a button, or a control panel. The electronic system 210 may further include one or more output devices 218 for outputting information (e.g., visual or audio output) to a user such as, for example, a monitor, a display, a printer, an audio output jack, a speaker, etc. In some embodiments, the input device 216 and the output device 218 may comprise a single touchscreen device that can be used both to input information to the electronic system 210 and to output visual information to a user. The input device 216 and the output device 218 may communicate electrically with one or more of the memory device 212 and the electronic signal processor device 214.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A microelectronic device, comprising:
a stack structure comprising tiers respectively including conductive material, the stack structure divided into blocks respectively comprising local word line (LWL) structures vertically stacked relative to one another and individually comprising a portion of the conductive material of one of the tiers;
block select (BS) devices vertically overlapping the blocks of the stack structure and respectively including a stack of transistors operatively associated with the LWL structures of one of the blocks; and
a global word line (GWL) stack vertically overlapping the BS devices and the blocks of the stack structure and comprising GWL structures vertically stacked relative to one another, the GWL stack operatively associated with multiple of the BS devices.

2. The microelectronic device of claim 1, wherein each transistor of the stack of transistors of a respective one of the BS devices individually horizontally extends from one of the LWL structures of the one of the blocks to one of the GWL structures of the GWL stack.

3. The microelectronic device of claim 1, wherein, for respective ones of BS devices, the stack of transistors thereof is horizontally oriented substantially perpendicular to the GWL stack.

4. The microelectronic device of claim 1, wherein, for respective ones of BS devices, the stack of transistors thereof is horizontally oriented substantially parallel to the GWL stack.

5. The microelectronic device of claim 1, further comprising a GWL staircase vertically overlapping the GWL stack and having steps defined my projections horizontally extending from the GWL structures of the GWL stack.

6. The microelectronic device of claim 1, wherein the blocks of the stack structure further respectively comprise upper select gate structures vertically overlying the LWL structures thereof, some of the upper select gate structures at different vertical elevations than one another ganged together with conductive routing.

7. The microelectronic device of claim 1, further comprising BS generator devices vertically offset from and coupled to the BS devices.

8. The microelectronic device of claim 7, further comprising BS contact structures vertically offset from and in physical contact with conductive gate material of respective ones of the BS devices, the BS contact structures coupled to the BS generator devices.

9. A microelectronic device, comprising:
a block array region comprising blocks horizontally extending in parallel in a first direction and separated from one another in a second direction orthogonal to the first direction by insulative slot structures, the blocks respectively comprising a stack of local word line (LWL) structures;
a global word line (GWL) region comprising a stack of GWL structures, the stack of GWL structures horizontally extending in the second direction and vertically overlapping the stack of LWL structures of respective ones of the blocks of the block array region; and
a block select (BS) region horizontally interposed between the block array region and the GWL region in the first direction, the BS region comprising BS devices respectively vertically overlapping and horizontally extending between the stack of GWL structures of the GWL region and the stack of LWL structures of the respective ones of the blocks of the block array region.

10. The microelectronic device of claim 9, wherein the BS devices of the BS region individually comprise transistors vertically stacked relative to one another and sharing a gate electrode with one another, the transistors respectively at a vertical position of and coupled to a GWL structure of the stack of GWL structures of the GWL region and a LWL structure of the stack of LWL structures of the respective ones of the blocks of the block array region.

11. The microelectronic device of claim 9, further comprising:
an additional block array region comprising additional blocks horizontally extending in parallel in the first direction and separated from one another in the second direction by additional insulative slot structure, the additional blocks respectively vertically overlapping the blocks of the block array region and comprising an additional stack of LWL structures; and
an additional BS region horizontally interposed between the additional block array region and the GWL region in the first direction, the additional BS region comprising additional BS devices respectively vertically overlapping and horizontally extending between the stack of GWL structures of the GWL region and the additional stack of LWL structures of the respective ones of the additional blocks of the additional block array region.

12. The microelectronic device of claim 11, wherein the stack of GWL structures is coupled to:
transistors of the BS devices of the BS region; and
additional transistors of the additional BS devices of the additional BS region.

13. The microelectronic device of claim 12, further comprising:
a GWL staircase structure having steps defined by projections horizontally extending in the first direction from the stack of GWL structures;
conductive contacts in physical contact with the steps of the GWL staircase; and
control logic circuitry vertically offset from the GWL staircase structure and coupled to the conductive contacts.

14. The microelectronic device of claim 13, wherein the GWL staircase structure is substantially confined within a horizontal area of the GWL region.

15. The microelectronic device of claim 11, wherein:
the GWL region further comprises an additional stack of GWL structures horizontally extending in the second direction and spaced apart from the stack of GWL structures in the first direction, the stack of GWL structures;
the stack of GWL structures is coupled to horizontally oriented transistors of the BS devices of the BS region; and
the additional stack of GWL structures is coupled to additional horizontally oriented transistors of the additional BS devices of the BS region.

16. The microelectronic device of claim 15, further comprising:
a GWL staircase structure having steps defined by projections horizontally extending in the first direction from the stack of GWL structures; and
an additional GWL staircase structure discrete form the GWL staircase structure and having additional steps defined by additional projections horizontally extending in the first direction from the additional stack of GWL structures.

17. The microelectronic device of claim 16, wherein the GWL staircase structure and additional GWL staircase structure are respectively horizontally positioned outside of a horizontal area of the GWL region.

18. A memory device, comprising:
blocks respectively comprising:
local word line (LWL) structures vertically stacked relative to one another; and
strings of memory cells vertically extending through the LWL structures;
a global word line (GWL) stack comprising GWL structures at vertical elevations of the LWL structures of respective ones of the blocks; and
block select (BS) devices horizontally interposed between the GWL stack and the blocks and respectively comprising transistors at the vertical elevations of the LWL structures of the respective ones of the blocks, the transistors individually horizontally extending from one of the GWL structures of the GWL stack to one of the LWL structures of one of the blocks.

19. The memory device of claim 18, wherein the blocks respectively further comprise:
select gate drain (SGD) structures vertically overlying the LWL structures, the GWL stack, and the BS devices; and
insulative slot structures vertically overlapping and horizontally alternating with groups of the SGD structures.

20. The memory device of claim 18, wherein:
the GWL structures of the GWL stack have projections horizontally extending therefrom in a first direction;
LWL structures of the blocks have additional projections horizontally extending therefrom in the first direction, the additional projections horizontally overlapping the projections of the GWL structures in the first direction and horizontally offset from the projections of the GWL structures in a second direction orthogonal to the first direction; and
the transistors of the BS devices respectively horizontally extend in the second direction from one of the projections of one of the GWL structures to one of the additional projections of one of the LWL structures.
